(19) United States
(12) Patent Application Publication
(10) Pub. No.: US 2024/0284601 A1
(43) Pub. Date: Aug. 22, 2024

(54) MANUFACTURING METHOD OF ELECTRONIC DEVICE

(71) Applicant: FUJIFILM Corporation, Tokyo (JP)

(72) Inventors: Norihide SHIMOHARA, Kanagawa (JP); Yusuke FUJII, Kanagawa (JP); Kazuo KAMOHARA, Kanagawa (JP); Kazuhiro YOKOI, Kanagawa (JP)

(73) Assignee: FUJIFILM Corporation, Tokyo (JP)

(21) Appl. No.: 18/644,077

(22) Filed: Apr. 23, 2024

Related U.S. Application Data
(63) Continuation of application No. PCT/JP2022/038998, filed on Oct. 19, 2022.

(30) Foreign Application Priority Data
Oct. 25, 2021 (JP) 2021-174077

(51) Int. Cl. H05K 3/12

(52) U.S. Cl. CPC H05K 3/125; H05K 3/1283; H05K 2203/013; H05K 2203/101

(57) ABSTRACT

Provided is a manufacturing method of an electronic device, including a step of preparing an electronic substrate including a wiring board, an electronic component, and a ground electrode, a first step of forming an insulating layer on the electronic component, and a second step of forming, on the insulating layer and on the ground electrode, an electromagnetic wave shielding layer that covers the insulating layer and is electrically connected to the ground electrode, to obtain an electronic device, in which, in the first step, the insulating layer is formed by applying an ink for an insulating layer and performing an irradiation with active energy ray on the applied ink for an insulating layer, in the second step, the electromagnetic wave shielding layer is formed by applying an ink for an electromagnetic wave shielding layer, containing a metal compound, and a jetting temperature of the ink for an insulating layer is higher than a jetting temperature of the ink for an electromagnetic wave shielding layer by 10° C. to 40° C.

### CROSS-REFERENCE TO RELATED APPLICATIONS

This application is a continuation application of International Application No. PCT/JP2022/038998, filed Oct. 19, 2022, the disclosure of which is incorporated herein by reference in its entirety. Further, this application claims priority from Japanese Patent Application No. 2021-174077, filed Oct. 25, 2021, the disclosure of which is incorporated herein by reference in its entirety.

### BACKGROUND OF THE INVENTION

### 1. Field of the Invention

The present disclosure relates to a manufacturing method of an electronic device.

### 2. Description of the Related Art

It is necessary that an electronic component is shielded from interference with electromagnetic waves from other electronic apparatuses, and the electronic component is generally covered with a shielding can.

The shielding can has problems such as being thick, heavy, and having a small degree of freedom in design.

Therefore, as a technique for shielding the electronic component from the electromagnetic waves, there is a demand for an alternative technique for the shielding can.

For example, JP2019-527463A discloses the following method as a method of manufacturing, using an inkjet printer, a printed circuit board having an electromagnetically shielded truck.

A method comprising:
a. providing an ink jet printing system including
   i. a first print head having: at least one aperture, an insulating resin ink reservoir, and an insulating resin pump configured to supply the insulating resin inkjet ink through the aperture,
   ii. a second print head having: at least one aperture, a first metallic ink reservoir, and a first metallic ink pump configured to supply the first metallic inkjet ink through the aperture,
   iii. a conveyor, operably coupled to the first, and the second print heads configured to convey a substrate to each of the first, and second print heads, and
   iv. a computer aided manufacturing (“CAM”) module including a data processor, a non-volatile memory, and a set of executable instructions stored thereon for receiving a visualization file of the printed circuit board having an electromagnetically-shielded track, generating a file that represents at least one, substantially 2D layer for printing the printed circuit board having an electromagnetically-shielded track; receiving a selection of parameters related to the printed circuit board having an electromagnetically-shielded track, and altering the file representing the at least one, substantially 2D layer based on at least one of the selection of parameters, in which the CAM module is configured to control each of the first, and second print heads;
b. providing the insulating resin inkjet ink composition, and the first metallic inkjet ink composition;
c. using the CAM module, obtaining a plurality of generated files, each representing a substantially 2D layer of the printed circuit board having an electromagnetically-shielded track for printing, each substantially 2D layer comprising a pattern representative of the insulating resin inkjet ink, and the first metallic inkjet ink; and
d. using the first inkjet print head, and the second print head, forming printed circuit board having an electromagnetically-shielded track and/or component in which the insulating resin ink
   i. forms a sleeve around a conducting track, in which the first metallic ink forms a shielding sleeve around the insulating resin sleeve; and/or
   ii. forms a housing around the conducting track, in which the first metallic ink forms a shielding capsule around the insulating resin housing.

### SUMMARY OF THE INVENTION

The present inventors have studied to manufacture an electronic device by preparing an electronic substrate including a wiring board, an electronic component disposed on the wiring board, and a ground electrode, forming an insulating layer on the electronic component in the electronic substrate using an ink jet ink for forming an insulating layer, and forming an electromagnetic wave shielding layer that covers the insulating layer and is electrically connected to the ground electrode using an ink jet ink for forming an electromagnetic wave shielding layer.

However, by the studies of the present inventors, it has been found that, in the manufactured electronic device in the manufacturing of the electronic device, at least one of a pattern quality of the insulating layer or electromagnetic wave-shielding properties of the electromagnetic wave shielding layer may be insufficient.

Here, the insufficient pattern quality of the insulating layer means that a pattern of the insulating layer is formed to protrude into an unintended region (for example, on the ground electrode) and/or an abnormal portion such as a streak is generated in the pattern of the insulating layer.

An object of an aspect of the present disclosure is to provide a manufacturing method of an electronic device, with which an electronic device having excellent pattern quality of an insulating layer and excellent electromagnetic wave-shielding properties of an electromagnetic wave shielding layer can be manufactured.

The specific methods for achieving the above-described object include the following aspects.

<1> A manufacturing method of an electronic device, comprising:
a preparation step of preparing an electronic substrate including a wiring board, an electronic component disposed on the wiring board, and a ground electrode;
a first step of forming an insulating layer on the electronic component; and
a second step of forming, on the insulating layer and on the ground electrode, an electromagnetic wave shielding layer that covers the insulating layer and is electrically connected to the ground electrode, to obtain an electronic device,
in which, in the first step, the insulating layer is formed by jetting an ink for an insulating layer, which is an active energy ray curable-type ink and has a viscosity at 25° C. of 12 mPa·s to 35 mPa·s, from an ink jet head A to apply the ink for an insulating layer onto the electronic component, and performing an irradiation with active energy ray on the applied ink for an insulating layer,
in the second step, the electromagnetic wave shielding layer is formed by jetting an ink for an electromagnetic wave shielding layer, which contains at least one metal compound selected from the group consisting of a metal salt and a metal complex, from an ink jet head B to apply the ink for an electromagnetic wave shielding layer onto the insulating layer and onto the ground electrode, and performing at least one of a heating or an irradiation with active energy ray on the applied ink for an electromagnetic wave shielding layer, and
a jetting temperature in the jetting of the ink for an insulating layer from the ink jet head A is higher than a jetting temperature in the jetting of the ink for an electromagnetic wave shielding layer from the ink jet head B by 10° C. to 40° C.

<2> The manufacturing method of an electronic device according to <1>,
in which, in the first step, a time from the application of the ink for an insulating layer onto the electronic component to a start of the irradiation with active energy ray is 0.50 seconds or less.

<3> The manufacturing method of an electronic device according to <1> or <2>,
in which, in the first step, the ink for an insulating layer is jetted from the ink jet head A while relatively moving the electronic substrate and the ink jet head A at a relative movement speed of 16 cm/sec or more.

<4> The manufacturing method of an electronic device according to any one of <1> to <3>,
in which the second step includes
   heating the electronic substrate before applying the ink for an electromagnetic wave shielding layer to a temperature of 50° C. or higher and lower than 110° C., and
   applying the ink for an electromagnetic wave shielding layer onto the insulating layer and onto the ground electrode in the electronic substrate heated to the temperature of 50° C. or higher and lower than 110° C.

<5> The manufacturing method of an electronic device according to any one of <1> to <4>,
in which, in the second step, a temperature of the electronic substrate in the jetting of the ink for an electromagnetic wave shielding layer from the ink jet head B is higher than the jetting temperature in the jetting of the ink for an electromagnetic wave shielding layer from the ink jet head B by 25° C. or higher.

<6> The manufacturing method of an electronic device according to any one of <1> to <5>.
in which, in the second step, the ink for an electromagnetic wave shielding layer is applied onto the insulating layer and onto the ground electrode in the electronic substrate at a resolution of 1,200 dpi or more.

<7> The manufacturing method of an electronic device according to any one of <1> to <6>,
in which the ink for an insulating layer contains a monofunctional acrylate.

<8> The manufacturing method of an electronic device according to <7>,
in which the monofunctional acrylate includes a monofunctional acrylate X satisfying at least one of a requirement that a molecular weight is 200 or more or a requirement that a ring structure is included.

<9> The manufacturing method of an electronic device according to <7> or <8>,
in which the monofunctional acrylate includes a monofunctional acrylate X2 satisfying both a requirement that a molecular weight is 200 or more and a requirement that a ring structure is included.

According to the aspect of the present disclosure, there is provided a manufacturing method of an electronic device, with which an electronic device having excellent pattern quality of an insulating layer and excellent electromagnetic wave-shielding properties of an electromagnetic wave shielding layer can be manufactured.

### BRIEF DESCRIPTION OF THE DRAWINGS

FIG. 1A is a schematic plan view of an electronic substrate prepared in a preparation step in an example of the present disclosure.

FIG. 1B is a cross-sectional view taken along a line X-X in FIG. 1A.

FIG. 2A is a schematic plan view showing a state in which an insulating layer is formed in a first step in the example of the present disclosure.

FIG. 2B is a cross-sectional view taken along a line X-X in FIG. 2A.

FIG. 3A is a schematic plan view showing a state in which an electromagnetic wave shielding layer is formed in a second step in the example of the present disclosure.

FIG. 3B is a cross-sectional view taken along a line X-X in FIG. 3A.

### DESCRIPTION OF THE PREFERRED EMBODIMENTS

In the present specification, a numerical range indicated using “to” means a range including numerical values described before and after “to” as a minimum value and a maximum value, respectively.

In a numerical range described in a stepwise manner in the present specification, an upper limit or a lower limit described in a certain numerical range may be replaced with an upper limit or a lower limit in another numerical range described in a stepwise manner. In addition, in a numerical range described in the present specification, an upper limit or a lower limit described in a certain numerical range may be replaced with a value described in Examples.

In the present specification, in a case in which a plurality of substances corresponding to respective components in a composition are present, the amount of the respective components in the composition means the total amount of the plurality of substances present in the composition unless otherwise specified.

In the present specification, a combination of two or more preferred aspects is a more preferred aspect.

In the present specification, the meaning of the term “step” includes not only an independent step but also a step whose intended purpose is achieved even in a case in which the step is not clearly distinguished from other steps.

In the present specification, “image” means general films, and “image recording” means formation of the image (that is, the film). In addition, the concept of “image” in the present specification also includes a solid image.

In the present specification, “(meth)acrylate” is a concept including both acrylate and methacrylate, “(meth)acryloyl group” is a concept including both an acryloyl group and a methacryloyl group, “(meth)acrylic acid” is a concept including both acrylic acid and methacrylic acid, and “(meth)acrylamide” is a concept including both acrylamide and methacrylamide.

### [Manufacturing Method of Electronic Device]

The manufacturing method of an electronic device according to the present disclosure (hereinafter, also referred to as “manufacturing method according to the present disclosure”) is a manufacturing method of an electronic device, including: a preparation step of preparing an electronic substrate including a wiring board, an electronic component disposed on the wiring board, and a ground electrode; a first step of forming an insulating layer on the electronic component; and a second step of forming, on the insulating layer and on the ground electrode, an electromagnetic wave shielding layer that covers the insulating layer and is electrically connected to the ground electrode, to obtain an electronic device, in which, in the first step, the insulating layer is formed by jetting an ink for an insulating layer, which is an active energy ray curable-type ink and has a viscosity at 25° C. of 12 mPa·s to 35 mPa·s, from an ink jet head A to apply the ink for an insulating layer onto the electronic component, and performing an irradiation with active energy ray on the applied ink for an insulating layer, in the second step, the electromagnetic wave shielding layer is formed by jetting an ink for an electromagnetic wave shielding layer, which contains at least one metal compound selected from the group consisting of a metal salt and a metal complex, from an ink jet head B to apply the ink for an electromagnetic wave shielding layer onto the insulating layer and onto the ground electrode, and performing at least one of a heating or an irradiation with active energy ray on the applied ink for an electromagnetic wave shielding layer, and a jetting temperature in the jetting of the ink for an insulating layer from the ink jet head A is higher than a jetting temperature in the jetting of the ink for an electromagnetic wave shielding layer from the ink jet head B by 10° C. to 40° C.

The manufacturing method of an electronic device according to the present disclosure may include other steps as necessary.

With the manufacturing method according to the present disclosure, an electronic device having excellent pattern quality of an insulating layer and excellent electromagnetic wave-shielding properties of an electromagnetic wave shielding layer can be manufactured.

Here, the “excellent pattern quality of an insulating layer” means that a pattern of the insulating layer is suppressed from being formed to protrude into an unintended region (for example, on the ground electrode) and an abnormal portion such as a streak is suppressed from being generated in the pattern of the insulating layer.

The reason why the above-described effects are exhibited is presumed as follows.

The reason why the pattern quality of the insulating layer in the manufactured electronic device is excellent is considered to be that an outflow of the ink for an insulating layer and a deterioration of jettability are suppressed as follows.

That is, it is considered that, by setting the viscosity at 25° C. (hereinafter, also simply referred to as “viscosity”) of the ink for an insulating layer, which is used for forming the insulating layer, to be 12 mPa·s or more, the outflow of the ink for an insulating layer, applied onto the electronic component, and the deterioration of jettability are suppressed.

Furthermore, it is considered that, by setting the viscosity of the ink for an insulating layer to be 35 mPa·s or less, the deterioration of jettability of the ink for an insulating layer, applied onto the electronic component, is suppressed.

It is considered that, by setting the jetting temperature in the jetting of the ink for an insulating layer from the ink jet head A to be higher than the jetting temperature in the jetting of the ink for an electromagnetic wave shielding layer from the ink jet head B by 10° C. or higher and 40° C. or lower, the deterioration of jettability of the ink for an insulating layer is suppressed even though the viscosity of the ink for an insulating layer is 12 mPa·s or more.

As one reason why the electromagnetic wave-shielding properties of the electromagnetic wave shielding layer are excellent, it is considered that the decrease in pattern quality of the insulating layer, which is a base of the electromagnetic wave shielding layer, is suppressed. Specifically, it is considered that, by suppressing the outflow of the ink for an insulating layer and the deterioration of jettability as described above, the decrease in pattern quality of the insulating layer is suppressed, and thus the deterioration in electromagnetic wave-shielding properties is suppressed in the electromagnetic wave shielding layer formed on the insulating layer.

As another reason why the electromagnetic wave-shielding properties of the electromagnetic wave shielding layer are excellent, it is considered that a resistance of the formed electromagnetic wave shielding layer is reduced. Specifically, it is considered that, by using, as the ink for an electromagnetic wave shielding layer, an ink for an electromagnetic wave shielding layer, which contains at least one metal compound selected from the group consisting of a metal salt and a metal complex, the resistance of the formed electromagnetic wave shielding layer is reduced as compared with a case of using an ink containing metal particles and not containing the metal compound.

<Example of Manufacturing Method of Electronic Device>

Hereinafter, an example of the manufacturing method according to the present disclosure will be described with reference to the drawings.

However, the manufacturing method according to the present disclosure and the electronic device manufactured by the manufacturing method according to the present disclosure are not limited to the following example.

In the following description, substantially the same elements (for example, components or parts) may be designated by the same reference numerals, and redundant description thereof may be omitted.

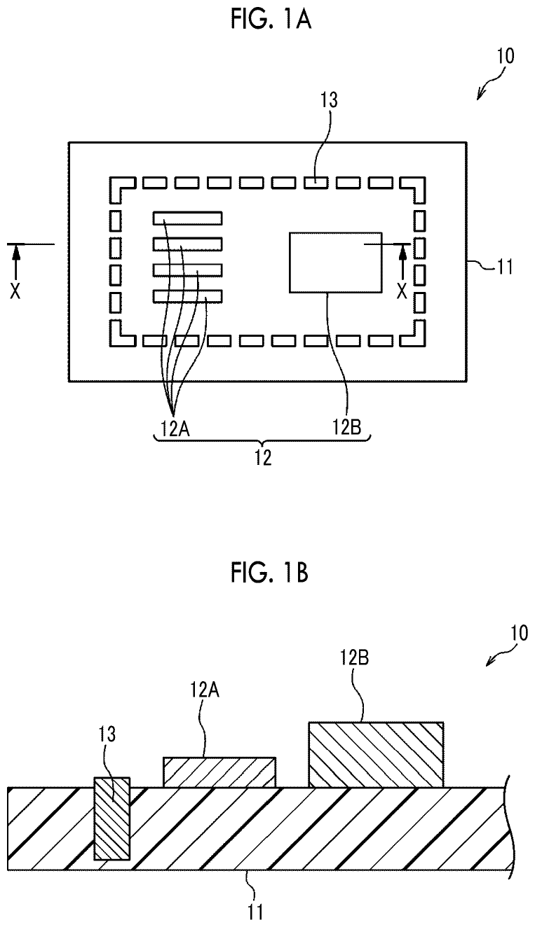

FIG. 1A is a schematic plan view of the electronic substrate prepared in the preparation step in the example of the present disclosure.

FIG. 1B is a cross-sectional view taken along a line X-X in FIG. 1A.

As shown in FIGS. 1A and 1B, in the preparation step, an electronic substrate 10 including a wiring board 11, an electronic component 12 (specifically, electronic components 12A and 12B) disposed on the wiring board 11, and a ground electrode 13 is prepared.

The wiring board 11 is a wiring board with a wiring on at least one of the substrate or the inside of the substrate, which is not shown.

Details of the preparation step and the electronic substrate will be described later.

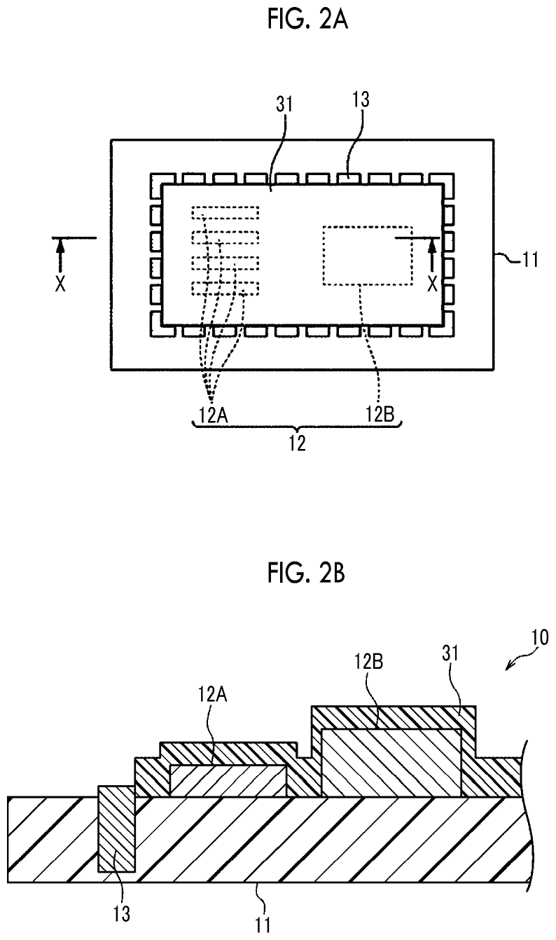

FIG. 2A is a schematic plan view showing a state in which the insulating layer is formed in the first step in the example of the present disclosure.

FIG. 2B is a cross-sectional view taken along a line X-X in FIG. 2A.

As shown in FIGS. 2A and 2B, in the first step, an insulating layer 31 is formed on the electronic components 12A and 12B in the electronic substrate 10.

As in the present example, the insulating layer 31 may be formed in a region straddling the electronic components 12A and 12B and a region where no electronic component is disposed.

In this example, the insulating layer 31 is formed in a disposition in contact with the ground electrode 13 in a plan view, but the insulating layer 31 may be formed in a disposition not in contact with the ground electrode 13. In addition, the insulating layer 31 may be formed to overlap a part of the ground electrode 13.

From the viewpoint of obtaining an insulating layer having a large thickness, the first step (that is, the formation of the insulating layer) may be repeatedly performed.

Details of the first step will be described later.

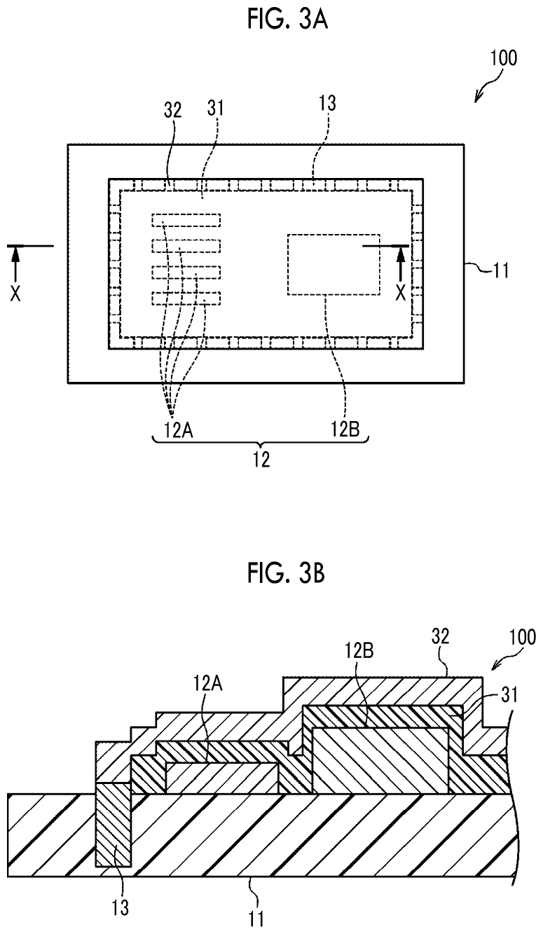

FIG. 3A is a schematic plan view showing a state in which the electromagnetic wave shielding layer is formed in the second step in the example of the present disclosure.

FIG. 3B is a cross-sectional view taken along a line X-X in FIG. 3A.

As shown in FIGS. 3A and 3B, in the second step, an electromagnetic wave shielding layer 32 is formed by applying the ink for an electromagnetic wave shielding layer, which is an ink for forming the electromagnetic wave shielding layer, onto the insulating layer 31 and onto the ground electrode 13.

The ink for an electromagnetic wave shielding layer contains a metal compound that is at least one selected from the group consisting of a metal salt and a metal complex.

In the second step, the ink for an electromagnetic wave shielding layer is jetted from the ink jet head B to be applied, and the applied ink for an electromagnetic wave shielding layer is subjected to at least one of heating or irradiation with active energy ray to form the electromagnetic wave shielding layer 32.

From the viewpoint of obtaining an electromagnetic wave shielding layer having a large thickness, the second step (that is, the formation of the electromagnetic wave shielding layer) may be repeatedly performed.

Details of the second step will be described later.

Next, each step of the manufacturing method according to the present disclosure will be described.

### <Preparation Step>

The manufacturing method according to the present disclosure includes a preparation step.

The preparation step is a step of preparing an electronic substrate (for example, the above-described electronic substrate 10) including a wiring board (for example, the above-described wiring board 11), an electronic component (for example, the above-described electronic components 12A and 12B) disposed on the wiring board, and a ground electrode (for example, the above-described ground electrode 13).

The preparation step may be a step of simply preparing the electronic substrate (for example, the above-described electronic substrate 10) manufactured in advance, or may be a step of manufacturing the electronic substrate.

As a manufacturing method of the electronic substrate, a known manufacturing method can be referred to.

Examples of the electronic substrate include a flexible print substrate, a rigid print substrate, and a rigid flexible substrate.

The wiring board (for example, the above-described wiring board 11) is a member with a wiring on at least one of the substrate or the inside of the substrate.

However, in the wiring board 11 in FIG. 1A and the like described above, the wiring is not shown.

Examples of the substrate constituting the wiring board include a glass epoxy substrate, a ceramic substrate, a polyimide substrate, and a polyethylene terephthalate substrate. The substrate may have a monolayer structure or a multilayer structure.

The wiring provided on the wiring board is preferably a copper wiring.

For example, one end of the wiring is connected to an external power supply, and the other end thereof is connected to a terminal of the electronic component.

Examples of the electronic component (for example, the above-described electronic components 12A and 12B) include a semiconductor chip, a capacitor, and a transistor.

The ground electrode (for example, the above-described ground electrode 13) is an electrode to which a ground (GND) potential is applied.

In the above-described example, the ground electrode 13 surrounds the electronic components 12A and 12B, and is formed in a discontinuous frame shape in a plan view, but a position and a shape of the ground electrode are not limited thereto.

For example, the ground electrode may be formed in a continuous frame shape in a plan view, or may be formed between the electronic component 12A and the electronic component 12B.

In addition, in FIGS. 1A and 1B, the ground electrode 13 is formed such that a part of the ground electrode 13 in a thickness direction is embedded in the wiring board 11, but the ground electrode in the present disclosure is not limited to this example. For example, the ground electrode may be formed on a surface of the wiring board 11 instead of being embedded in the wiring board 11. In addition, the ground electrode may be formed as a pattern that penetrates the wiring board 11.

A height of the ground electrode is preferably 150 μm or less and more preferably 120 μm or less based on a surface of the wiring board on a side where the electronic components are disposed. The lower limit value of the height is not particularly limited, but is, for example, 30 μm.

### <First Step>

The manufacturing method according to the present disclosure includes a first step.

The first step is a step of applying an ink for an insulating layer onto the electronic component to form an insulating layer (for example, the insulating layer 31).

The insulating layer formed in the first step is a layer having insulating properties.

In the present disclosure, the insulating properties mean properties of having a volume resistivity of 10¹⁰Ω·cm or more.

### (Ink for Insulating Layer)

The viscosity of the ink for an insulating layer is 12 mPa·s to 35 mPa·s.

In a case in which the viscosity of the ink for an insulating layer is 12 mPa·s or more, the outflow of the ink for an insulating layer, applied onto the electronic component and the deterioration of jettability are suppressed, and as a result, the pattern quality of the formed insulating layer is improved.

In a case in which the viscosity of the ink for an insulating layer at 25° C. is 35 mPa·s or less, the decrease in jettability of the ink is suppressed, and as a result, the pattern quality of the formed insulating layer is improved.

The viscosity of the ink for an insulating layer is preferably 15 mPa·s to 30 mPa·s and more preferably 20 mPa·s to 30 mPa·s.

The viscosity of the ink in the present disclosure is a value measured at 25° C. using a viscometer (for example, a TV-22 type viscometer manufactured by Toki Sangyo Co., Ltd.).

The ink for an insulating layer is an active energy ray curable-type ink.

The ink for an insulating layer preferably contains a polymerizable monomer and a polymerization initiator.

### —Polymerizable Monomer—

The polymerizable monomer refers to a monomer having at least one polymerizable group in one molecule. The polymerizable group in the polymerizable monomer may be a cationically polymerizable group or a radically polymerizable group. In addition, from the viewpoint of curing properties, the radically polymerizable group is preferably an ethylenically unsaturated group. From the viewpoint of curing properties, the cationically polymerizable group is preferably a group containing at least one of an oxirane ring or an oxetane ring.

In the present disclosure, the monomer refers to a compound having a molecular weight of 1,000 or less. The molecular weight can be calculated from the type and number of atoms constituting the compound.

The polymerizable monomer may be a monofunctional monomer having one polymerizable group, or a polyfunctional monomer (that is, a bi- or higher functional monomer) having two or more polymerizable groups.

The monofunctional monomer is not particularly limited as long as it is a monomer having one polymerizable group.

### —Radically Polymerizable Monomer—

From the viewpoint of durability of the formed insulating layer, the radically polymerizable monomer preferably includes a monofunctional ethylenically unsaturated monomer.

Examples of the monofunctional ethylenically unsaturated monomer include monofunctional (meth)acrylate, monofunctional (meth)acrylamide, a monofunctional aromatic vinyl compound, monofunctional vinyl ether, and a monofunctional N-vinyl compound.

Examples of the monofunctional (meth)acrylate include methyl (meth)acrylate, ethyl (meth)acrylate, propyl (meth)acrylate, n-butyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, lauryl (meth)acrylate, stearyl (meth)acrylate, isostearyl (meth)acrylate, cyclohexyl (meth)acrylate, 4-n-butylcyclohexyl (meth)acrylate, 4-tert-butylcyclohexyl (meth)acrylate, bornyl (meth)acrylate, isobornyl (meth)acrylate, 2-ethylhexyldiglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, 3-methoxybutyl (meth)acrylate, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, 2-phenoxymethyl (meth)acrylate, 2-phenoxyethyl (meth)acrylate, glycidyl (meth)acrylate, glycidyloxybutyl (meth)acrylate, glycidyloxyethyl (meth)acrylate, glycidyloxypropyl (meth)acrylate, tetrahydrofurfuryl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 3-hydroxybutyl (meth)acrylate, 4-hydroxybutyl (meth)acrylate, cyclic trimethylolpropane formal (meth)acrylate, phenylglycidyl ether (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethylsilylpropyl (meth)acrylate, polyethylene oxide monomethyl ether (meth)acrylate, polyethylene oxide (meth)acrylate, polyethylene oxide monoalkyl ether (meth)acrylate, dipropylene glycol (meth)acrylate, polypropylene oxide monoalkyl ether (meth)acrylate, 2-methacryloyloxyethyl succinate, 2-methacryloyloxyhexahydrophthalic acid, 2-methacryloyloxyethyl-2-hydroxypropyl phthalate, ethoxydiethylene glycol (meth)acrylate, butoxydiethylene glycol (meth)acrylate, trifluoroethyl (meth)acrylate, perfluorooctylethyl (meth)acrylate, 2-hydroxy-3-phenoxypropyl (meth)acrylate, ethylene oxide (EO)-modified phenol (meth)acrylate, EO-modified cresol (meth)acrylate, EO-modified nonylphenol (meth)acrylate, propylene oxide (PO)-modified nonylphenol (meth)acrylate, EO-modified-2-ethylhexyl (meth)acrylate, dicyclopentenyl (meth)acrylate, dicyclopentenyloxyethyl (meth)acrylate, dicyclopentanyl (meth)acrylate, (3-ethyl-3-oxetanylmethyl) (meth)acrylate, phenoxyethylene glycol (meth)acrylate, 2-carboxyethyl (meth)acrylate, and 2-(meth)acryloyloxyethyl succinate.

Among these, the monofunctional (meth)acrylate is preferably a monofunctional (meth)acrylate having an aromatic ring or an aliphatic ring, and is more preferably isobornyl (meth)acrylate, 4-tert-butylcyclohexyl (meth)acrylate, dicyclopentenyl (meth)acrylate, or dicyclopentanyl (meth)acrylate.

From the viewpoint of improving the durability of the formed insulating layer, improving the jettability from the ink jet head A, and improving the pattern quality of the insulating layer, it is preferable that the ink for an insulating layer contains a monofunctional monomer.

In this case, the content of the monofunctional monomer is preferably 10% by mass or more, more preferably 20% by mass or more, and still more preferably 30% by mass or more with respect to the total amount of the ink for an insulating layer.

The upper limit of the content of the monofunctional monomer is, for example, 98% by mass, 90% by mass, 80% by mass, 70% by mass, or the like with respect to the total amount of the ink for an insulating layer.

From the viewpoint of further improving the durability of the formed insulating layer, it is preferable that the ink for an insulating layer contains a monofunctional acrylate.

In this case, the content of the monofunctional acrylate is preferably 10% by mass or more and more preferably 20% by mass or more with respect to the total amount of the ink for an insulating layer.

The upper limit of the content of the monofunctional acrylate is, for example, 98% by mass, 90% by mass, 80% by mass, 70% by mass, or the like with respect to the total amount of the ink for an insulating layer.

From the viewpoint of further improving the durability of the formed insulating layer, the above-described monofunctional acrylate that can be contained in the ink for an insulating layer more preferably includes a monofunctional acrylate X satisfying at least one of a requirement that a molecular weight is 200 or more or a requirement that a ring structure is included.

As the monofunctional acrylate X, a monofunctional acrylate X2 satisfying both the requirement that a molecular weight is 200 or more and the requirement that a ring structure is included is particularly preferable.

As the monofunctional acrylate X2 satisfying both the requirement that a molecular weight is 200 or more and the requirement that a ring structure is included, isobornyl acrylate, cyclic trimethylolpropane formal monomethacrylate, 4-tert-butylcyclohexyl acrylate, dicyclopentenyl acrylate, or dicyclopentanyl acrylate is preferable.

Examples of the monofunctional (meth)acrylamide include (meth)acrylamide, N-methyl (meth)acrylamide, N-ethyl (meth)acrylamide, N-propyl (meth)acrylamide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound include styrene, dimethylstyrene, trimethylstyrene, isopropylstyrene, chloromethylstyrene, methoxystyrene, acetoxystyrene, chlorostyrene, dichlorostyrene, bromostyrene, vinyl benzoic acid methyl ester, 3-methylstyrene, 4-methylstyrene, 3-ethylstyrene, 4-ethylstyrene, 3-propylstyrene, 4-propylstyrene, 3-butylstyrene, 4-butylstyrene, 3-hexylstyrene, 4-hexylstyrene, 3-octylstyrene, 4-octylstyrene, 3-(2-ethylhexyl)styrene, 4-(2-ethylhexyl)styrene, allyl styrene, isopropenyl styrene, butenyl styrene, octenyl styrene, 4-t-butoxycarbonyl styrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional N-vinyl compound include N-vinyl-8-caprolactam and N-vinylpyrrolidone.

### —Polyfunctional Polymerizable Monomer—

From the viewpoint of further improving the curing properties of the formed insulating layer, it is also preferable that the ink for an insulating layer contains a polyfunctional polymerizable monomer.

In this case, the content of the polyfunctional polymerizable monomer is preferably 10% by mass or more, more preferably 20% by mass or more, and still more preferably 30% by mass or more with respect to the total amount of the ink for an insulating layer.

The upper limit of the content of the polyfunctional polymerizable monomer is, for example, 98% by mass, 90% by mass, 80% by mass, 70% by mass, or the like with respect to the total amount of the ink for an insulating layer.

The polyfunctional polymerizable monomer is not particularly limited as long as it is a monomer having two or more polymerizable groups. From the viewpoint of curing properties, the polyfunctional polymerizable monomer is preferably a polyfunctional radically polymerizable monomer, and more preferably a polyfunctional ethylenically unsaturated monomer.

Examples of the polyfunctional ethylenically unsaturated monomer include a polyfunctional (meth)acrylate compound and a polyfunctional vinyl ether.

Examples of the polyfunctional (meth)acrylate include:
bifunctional (meth)acrylates such as ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, butylene glycol di(meth)acrylate, tetraethylene glycol di(meth)acrylate, neopentyl glycol di(meth)acrylate, 3-methyl-1,5-pentanediol di(meth)acrylate, 1,6-hexanediol di(meth)acrylate, heptanediol di(meth)acrylate, EO-modified neopentyl glycol di(meth)acrylate, PO-modified neopentyl glycol di(meth)acrylate, alkoxylated neopentyl glycol di(meth)acrylate, EO-modified hexanediol di(meth)acrylate, PO-modified hexanediol di(meth)acrylate, alkoxylated hexanediol di(meth)acrylate, octanediol di(meth)acrylate, nonanediol di(meth)acrylate, decanediol di(meth)acrylate, dodecanediol di(meth)acrylate, glycerin di(meth)acrylate, pentaerythritol di(meth)acrylate, ethylene glycol diglycidyl ether di(meth)acrylate, diethylene glycol diglycidyl ether di(meth)acrylate, and tricyclodecane dimethanol di(meth)acrylate; and
tri- or higher functional (meth)acrylates such as trimethylol ethane tri(meth)acrylate, trimethylol propane tri(meth)acrylate, trimethylol propane EO-added tri(meth)acrylate, pentaerythritol tri(meth)acrylate, pentaerythritol tetra(meth)acrylate, dipentaerythritol tetra(meth)acrylate, dipentaerythritol penta(meth)acrylate, dipentaerythritol hexa(meth)acrylate, tri(meth)acryloyloxyethoxytrimethylolpropane, glycerin polyglycidyl ether poly(meth)acrylate, and tris(2-acryloyloxyethyl) isocyanurate.

Examples of the polyfunctional vinyl ether include 1,4-butanediol divinyl ether, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, 1,4-cyclohexanedimethanol divinyl ether, bisphenol A alkylene oxide divinyl ether, bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether.

Among these, from the viewpoint of curing properties, the polyfunctional polymerizable monomer is preferably a monomer having 3 to 11 carbon atoms in a portion other than a (meth)acryloyl group. As the monomer having 3 to 11 carbon atoms in a portion other than a (meth)acryloyl group, specifically, 1,6-hexanediol di(meth)acrylate, dipropylene glycol di(meth)acrylate, PO-modified neopentyl glycol di(meth)acrylate, 1,4-butanediol di(meth)acrylate, 3-methyl-1,5-pentanediol di(meth)acrylate, polyethylene glycol di(meth)acrylate (EO chain n=4 to 23), or 1,10-decanediol di(meth)acrylate is more preferable.

### —Cationically Polymerizable Monomer—

As the cationically polymerizable monomer, a known cationically polymerizable monomer such as a compound (also referred to as an “oxirane compound” or an “epoxy compound”) having an oxirane ring (also referred to as an “epoxy ring”), a compound (also referred to as an “oxetane compound”) having an oxetane ring, and a vinyl ether compound can be used without particular limitation, from the viewpoint of curing properties.

The cationically polymerizable monomer is not particularly limited as long as it is a compound that initiates a polymerization reaction with cationic polymerization initiating species generated from a photocationic polymerization initiator described below and is cured, and various known cationically polymerizable monomers known as a photocationically polymerizable monomer can be used.

Examples of the cationically polymerizable monomer include an epoxy compound, a vinyl ether compound, and an oxetane compound, which are disclosed in JP1994-9714A (JP-H6-9714A), JP2001-31892A, JP2001-40068A, JP2001-55507A, JP2001-310938A, JP2001-310937A, and JP2001-220526A.

In addition, as the cationically polymerizable monomer, for example, a cationic polymerization-based photocurable resin is known, and recently, a photocationic polymerization-based photocurable resin sensitized in a visible light wavelength of 400 nm or more has been disclosed, for example, in JP1994-43633A (JP-H6-43633A) and JP1996-324137A (JP-H8-324137A).

A content of the polymerizable monomer is preferably 10% by mass or more and more preferably 50% by mass or more with respect to the total amount of the ink for an insulating layer.

The upper limit of the content of the polymerizable monomer is, for example, 98% by mass with respect to the total amount of the ink for an insulating layer.

### —Polymerization Initiator—

The ink for an insulating layer preferably contains a polymerization initiator.

As the polymerization initiator, a suitable polymerization initiator can be selected from a radical polymerization initiator or a cationic polymerization initiator depending on a type of the polymerizable monomers. Examples of the polymerization initiator include an oxime compound, an alkylphenone compound, an acylphosphine compound, an aromatic onium salt compound, an organic peroxide, a thio compound, a hexaarylbisimidazole compound, a borate compound, an azinium compound, a titanocene compound, an active ester compound, a carbon halogen bond-containing compound, and an alkylamine.

The polymerization initiator contained in the ink for an insulating layer is preferably at least one selected from the group consisting of an oxime compound, an alkylphenone compound, and a titanocene compound, more preferably an alkylphenone compound, and still more preferably at least one selected from the group consisting of an α-aminoalkylphenone compound and a benzyl ketal.

The cationic polymerization initiator is preferably a photoacid generator.

As the photoacid generator, for example, a compound used for a chemically amplified photoresist or photocationic polymerization is used (refer to “Organic Material for Imaging” edited by The Organic Electronics Materials Research Association, Bun-shin Publication (1993), 187 to 192 pages). Among these, the photoacid generator is preferably an aromatic onium salt compound, more preferably an onium salt compound such as a diazonium salt, a phosphonium salt, a sulfonium salt, or an iodonium salt, and still more preferably a sulfonium salt or an iodonium salt.

The content of the polymerization initiator is preferably 0.5% by mass to 20% by mass, and more preferably 2% by mass to 10% by mass, with respect to the total amount of the ink for an insulating layer.

In the present disclosure, the ink for an insulating layer may contain other components different from the polymerization initiator and the polymerizable monomer. Examples of the other components include a polymerizable oligomer, a chain transfer agent, a polymerization inhibitor, a sensitizer, a surfactant, and an additive.

### —Polymerizable Oligomer—

The ink for an insulating layer may contain a polymerizable oligomer as the polymerizable compound.

Here, the polymerizable oligomer means a polymerizable compound having a weight-average molecular weight of 1,000 to 10,000 and having at least one polymerizable group.

From the viewpoint of polymerization properties, the polymerizable group in the polymerizable oligomer is preferably a (meth)acryloyl group, a vinyl ether group, or an epoxy group.

Among these, an acryloyl group is more preferable.

Examples of the polymerizable oligomer include a polyester acrylate oligomer that is a polyester having one or more polymerizable groups, a urethane acrylate oligomer that is a polyurethane having one or more polymerizable groups, a modified polyether acrylate oligomer that is a modified polyether resin having one or more polymerizable groups, and an epoxy acrylate oligomer that is an epoxy resin-modified product having one or more polymerizable groups.

### —Chain Transfer Agent

The ink for an insulating layer may contain at least one chain transfer agent.

From the viewpoint of improving reactivity of photopolymerization reaction, the chain transfer agent is preferably a polyfunctional thiol.

Examples of the polyfunctional thiol include aliphatic thiols such as hexane-1,6-dithiol, decane-1,10-dithiol, dimercaptodiethyl ether, and dimercaptodiethyl sulfide, aromatic thiols such as xylylene dimercaptan, 4,4′-dimercaptodiphenylsulfide, and 1,4-benzenedithiol;
poly(mercaptoacetate) of a polyhydric alcohol such as ethylene glycol bis(mercaptoacetate), polyethylene glycol bis(mercaptoacetate), propylene glycol bis(mercaptoacetate), glycerin tris(mercaptoacetate), trimethylolethane tris(mercaptoacetate), trimethylolpropane tris(mercaptoacetate), pentaerythritol tetrakis(mercaptoacetate), and dipentaerythritol hexakis(mercaptoacetate);
poly(3-mercaptopropionate) of a polyhydric alcohol such as ethylene glycol bis(3-mercaptopropionate), polyethylene glycol bis(3-mercaptopropionate), propylene glycol bis(3-mercaptopropionate), glycerin tris(3-mercaptopropionate), trimethylolethane tris(mercaptopropionate), trimethylolpropane tris(3-mercaptopropionate), pentaerythritol tetrakis(3-mercaptopropionate), and dipentaerythritol hexakis(3-mercaptopropionate); and
poly(mercaptobutyrate) such as 1,4-bis(3-mercaptobutyryloxy)butane, 1,3,5-tris(3-mercaptobutyloxyethyl)-1,3,5-triazine-2,4,6(1H,3H,5H)-trione, and pentaerythritol tetrakis(3-mercaptobutyrate).

### —Polymerization Inhibitor—

The ink for an insulating layer may contain at least one polymerization inhibitor.

Examples of the polymerization inhibitor include p-methoxyphenol, quinones (for example, hydroquinone, benzoquinone, and methoxybenzoquinone), phenothiazine, catechols, alkylphenols (for example, dibutyl hydroxy toluene (BHT)), alkyl bisphenols, zinc dimethyldithiocarbamate, copper dimethyldithiocarbamate, copper dibutyldithiocarbamate, copper salicylate, thiodipropionic acid esters, mercaptobenzimidazole, phosphites, 2,2,6,6-tetramethylpiperidine-1-oxyl (TEMPO), 2,2,6,6-tetramethyl-4-hydroxypiperidine-1-oxyl (TEMPOL), and tris(N-nitroso-N-phenylhydroxylamine)aluminum salt (also known as Cupferron Al).

Among these, as the polymerization inhibitor, at least one selected from p-methoxyphenol, catechols, quinones, alkylphenols, TEMPO, TEMPOL, and tris(N-nitroso-N-phenylhydroxylamine)aluminum salt is preferable, and at least one selected from p-methoxyphenol, hydroquinone, benzoquinone, BHT, TEMPO, TEMPOL, and tris(N-nitroso-N-phenylhydroxylamine)aluminum salt is more preferable.

In a case in which the ink for an insulating layer contains a polymerization inhibitor, the content of the polymerization inhibitor is preferably 0.01% by mass to 2.0% by mass, more preferably 0.02% by mass to 1.0% by mass, and particularly preferably 0.03% by mass to 0.5% by mass, with respect to the total amount of the ink.

### —Sensitizer—

The ink for an insulating layer may contain at least one sensitizer.

Examples of the sensitizer include a polynuclear aromatic compound (for example, pyrene, perylene, triphenylene, and 2-ethyl-9,10-dimethoxyanthracene), a xanthene-based compound (for example, fluorescein, eosin, erythrosin, rhodamine B, and rose bengal), a cyanine-based compound (for example, thiacarbocyanine and oxacarbocyanine), a merocyanine-based compound (for example, merocyanine and carbomerocyanine), a thiazine-based compound (for example, thionine, methylene blue, and toluidine blue), an acridine-based compound (for example, acridine orange, chloroflavine, and acryflavine), anthraquinones (for example, anthraquinone), a squarylium-based compound (for example, squarylium), a coumarin-based compound (for example, 7-diethylamino-4-methylcoumarin), a thioxanthone-based compound (for example, isopropylthioxanthone), and a thiochromanone-based compound (for example, thiochromanone). Among these, the sensitizer is preferably a thioxanthone-based compound.

In a case in which the ink for an insulating layer contains a sensitizer, the content of the sensitizer is not particularly limited, but is preferably 1.0% by mass to 15.0% by mass and more preferably 1.5% by mass to 5.0% by mass with respect to the total amount of the ink.

### —Surfactant—

The ink for an insulating layer may contain at least one surfactant.

Examples of the surfactant include surfactants described in JP1987-173463A (JP-S62-173463A) and JP1987-183457A (JP-S62-183457A).

In addition, examples of the surfactant include anionic surfactants such as dialkyl sulfosuccinate, alkyl naphthalene sulfonate, and a fatty acid salt; nonionic surfactants such as polyoxyethylene alkyl ether, polyoxyethylene alkyl allyl ether, acetylene glycol, and a polyoxyethylene-polyoxypropylene block copolymer; and cationic surfactants such as an alkylamine salt and a quaternary ammonium salt.

In addition, the surfactant may be a fluorine-based surfactant or a silicone-based surfactant.

### —Organic Solvent—

The ink for an insulating layer may contain at least one organic solvent.

Examples of the organic solvent include (poly)alkylene glycol monoalkyl ethers such as ethylene glycol monoethyl ether, diethylene glycol monoethyl ether, triethylene glycol monomethyl ether, propylene glycol monomethyl ether (PGME), dipropylene glycol monomethyl ether, and tripropylene glycol monomethyl ether; (poly)alkylene glycol dialkyl ethers such as ethylene glycol dibutyl ether, diethylene glycol dimethyl ether, diethylene glycol diethyl ether, dipropylene glycol diethyl ether, and tetraethylene glycol dimethyl ether; (poly)alkylene glycol acetates such as diethylene glycol acetate; (poly)alkylene glycol diacetates such as ethylene glycol diacetate and propylene glycol diacetate; (poly)alkylene glycol monoalkyl ether acetates such as ethylene glycol monobutyl ether acetate and propylene glycol monomethyl ether acetate, ketones such as methyl ethyl ketone and cyclohexanone; lactones such as γ-butyrolactone; esters such as ethyl acetate, propyl acetate, butyl acetate, 3-methoxybutyl acetate (MBA), methyl propionate, and ethyl propionate; cyclic ethers such as tetrahydrofuran and dioxane; and amides such as dimethylformamide and dimethylacetamide.

In a case in which the ink for an insulating layer contains an organic solvent, the content of the organic solvent is preferably 70% by mass or less and more preferably 50% by mass or less with respect to the total amount of the ink.

A lower limit of the content of the organic solvent is not particularly limited.

### —Additive—

As necessary, the ink for an insulating layer may contain an additive such as a co-sensitizer, an ultraviolet absorber, an antioxidant, an antifading agent, and a basic compound.

### —Physical Properties—

From the viewpoint of improving jetting stability in a case in which the ink for an insulating layer is applied by using an ink jet recording method, a pH of the ink for an insulating layer is preferably 7 to 10, and more preferably 7.5 to 9.5. The pH is measured at 25° C. using a pH meter, such as a pH meter (model number “HM-31”) manufactured by DKK-Toa Corporation.

The surface tension of the ink for an insulating layer is preferably 60 mN/m or less, more preferably 20 mN/m to 50 mN/m, and still more preferably 25 mN/m to 45 mN/m.

The surface tension is measured at 25° C. using a surface tension meter, for example, by a plate method using an automatic surface tension meter (trade name, “CBVP-Z”) manufactured by Kyowa Interface Science Co., Ltd.

### (Application of Ink for Insulating Layer)

In the first step, the ink for an insulating layer is jetted from the ink jet head A (that is, an ink jet head for jetting the ink for an insulating layer) to be applied onto the electronic component.

The method of jetting the ink from the ink jet head may be any of an electric charge control method of jetting an ink by using electrostatic attraction force, a drop-on-demand method (pressure pulse method) using a vibration pressure of a piezo element, an acoustic ink jet method of jetting an ink by using a radiation pressure by means of converting electric signals into acoustic beams and irradiating the ink with the acoustic beams, or a thermal ink jet (Bubble Jet (registered trademark)) method of forming air bubbles by heating an ink and using the generated pressure.

As the method of jetting the ink from the ink jet head, particularly, an ink jet recording method, described in JP1979-59936A (JP-S54-59936A), of jetting an ink from a nozzle using an action force caused by a rapid change in volume of the ink after being subjected to an action of thermal energy can be effectively used.

In addition, regarding the method of jetting the ink from the ink jet head, the method described in paragraphs 0093 to 0105 of JP2003-306623A can also be referred to.

In the first step, it is preferable to jet the ink for an insulating layer from the ink jet head A while relatively moving the electronic substrate and the ink jet head A.

A relative movement speed in this case is preferably 16 cm/sec or more.

As a result, it is easy to adjust the time from the application of the ink for an insulating layer onto the electronic component to the start of the irradiation with active energy ray to be short (for example, it is easy to adjust the time to 0.50 seconds or less), and thus, it is easy to further improve the pattern quality of the insulating layer.

The upper limit of the above-described relative movement speed is not particularly limited, and examples thereof include 50 cm/sec and 40 cm/sec.

Examples of a recording method of relatively moving the electronic substrate and the ink jet head A include a shuttle scan method in which, using a serial head having a short length as the ink jet head A, recording is performed while scanning the serial head in a width direction of the electronic substrate, and a line method of using, as the ink jet head A, a line head in which recording elements are arranged to correspond to an entire region of one side of the electronic substrate.

In the shuttle scan method, the electronic substrate and the ink jet head A can be moved relative to each other by scanning the ink jet head and not scanning the electronic substrate. In this case, a scanning speed of the ink jet head corresponds to the relative movement speed between the electronic substrate and the ink jet head A.

In the line method, the line head may be fixed and the electronic substrate may be transported to relatively move the electronic substrate and the ink jet head A. In this case, a transportation speed of the electronic substrate corresponds to the relative movement speed between the electronic substrate and the ink jet head A.

An amount of droplets in the application of the ink for an insulating layer onto the electronic component (that is, in a case of jetting the ink for an insulating layer from the ink jet head A) is preferably 1 pL (picoliter) to 100 pL, more preferably 3 pL to 80 pL, and still more preferably 3 pL to 20 pL.

A resolution in the application of the ink for an insulating layer onto the electronic component (that is, in a case of jetting the ink for an insulating layer from the ink jet head A) is preferably 600 dpi or more and more preferably 1,200 dpi or more.

As a result, the pattern quality of the insulating layer can be further improved.

The upper limit of the above-described resolution is, for example, 3,000 dpi.

In the present disclosure, the dpi is an abbreviation for dot per inch.

From the viewpoint of further improving the pattern quality of the insulating layer, a jetting frequency in the application of the ink for an insulating layer onto the electronic component (that is, in a case of jetting the ink for an insulating layer from the ink jet head A) is preferably 1 kHz to 30 kHz, more preferably 5 kHz to 30 kHz, and still more preferably 10 kHz to 30 kHz.

(Irradiation with Active Energy Ray)

In the first step, the insulating layer is formed by irradiating the ink for an insulating layer, applied onto the electronic substrate, with active energy ray.

Examples of the active energy ray include ultraviolet rays, visible rays, and electron beams. Among these, ultraviolet rays (hereinafter, also referred to as “UV”) are preferable.

A peak wavelength of the ultraviolet rays is preferably 200 nm to 405 nm, more preferably 250 nm to 400 nm, and still more preferably 300 nm to 400 nm.

From the viewpoint of further suppressing the outflow of the ink for an insulating layer, the illuminance during the irradiation with active energy ray is preferably 1 W/cm² or more, and more preferably 10 W/cm² or more. An upper limit of the illuminance is not particularly limited, but is, for example, 100 W/cm².

An exposure amount during the irradiation with active energy ray is preferably 100 mJ/cm² to 10,000 mJ/cm², and more preferably 300 mJ/cm² to 5,000 mJ/cm².

In a case in which the application of the ink for an insulating layer and the irradiation of the ink for an insulating layer with active energy ray are defined as one cycle, the exposure amount mentioned herein means the exposure amount of the active energy ray in one cycle.

As a light source for ultraviolet irradiation, a mercury lamp, a gas laser, and a solid-state laser are mainly used, and a mercury lamp, a metal halide lamp, and an ultraviolet fluorescent lamp are widely known. In addition, a light emitting diode (UV-LED) and a laser diode (UV-LD) are compact, long-life, highly efficient, and low-cost, and are expected to be used as the light source for ultraviolet irradiation. Among these, the light source for ultraviolet irradiation is preferably a metal halide lamp, a high-pressure mercury lamp, a medium-pressure mercury lamp, a low-pressure mercury lamp, or UV-LED.

(Time from Application of Ink for Insulating Layer to Start of Irradiation with Active Energy Ray)

In the first step, the time from the application of the ink for an insulating layer onto the electronic component to the start of the irradiation with active energy ray is not particularly limited, but is preferably 0.50 seconds or less.

In a case where the above-described time is 0.50 seconds or less, the fluidity of the ink for an insulating layer, applied onto the electronic component, is more quickly suppressed, the outflow of the ink for an insulating layer is further suppressed, and as a result, the pattern quality of the insulating layer is further improved.

Here, the “from the application of the ink for an insulating layer onto the electronic component” means from immediately before a timing at which the ink for an insulating layer lands on the electronic component.

The application of the ink for an insulating layer and the irradiation with active energy ray in the first step can be performed by, for example, using a unit including the ink jet head A and a light source for irradiation with active energy ray, and relatively moving the unit and the electronic substrate. In the above-described unit, the ink jet head A and the light source for irradiation with active energy ray are arranged in the direction of the above-described relative movement.

In this case, the time from the application of the ink for an insulating layer to the start of the irradiation with active energy ray can be obtained as an approximate value obtained by dividing a distance between the ink jet head A and the light source for irradiation with active energy ray by the relative movement speed. Specifically, since the flight speed of the ink is extremely high, the time from the jetting of the ink from the ink jet head A to the arrival of the ink on the electronic component in the electronic substrate can be ignored.

From the viewpoint of further improving the pattern quality of the insulating layer, the time from the application of the ink for an insulating layer onto the electronic component to the start of the irradiation with active energy ray is preferably 0.45 seconds or less.

From the viewpoint of stability of the insulating layer forming process, the lower limit of the time from the application of the ink for an insulating layer onto the electronic component to the start of the irradiation with active energy ray is preferably 0.05 seconds, more preferably 0.10 seconds, still more preferably 0.15 seconds, and even more preferably 0.20 seconds.

### (Jetting Temperature of Ink for Insulating Layer)

The jetting temperature in the jetting of the ink for an insulating layer from the ink jet head A is higher than the jetting temperature in the jetting of the ink for an electromagnetic wave shielding layer from the ink jet head B, which will be described later, by 10° C. to 40° C.

That is, a value obtained by subtracting the jetting temperature of the ink for an insulating layer from the jetting temperature of the ink for an electromagnetic wave shielding layer is 10° C. to 40° C.

As a result, even in a case in which the viscosity of the ink for an insulating layer is 12 mPa·s or more, the decrease in jettability of the ink for an insulating layer is suppressed, and as a result, the pattern quality of the insulating layer is improved.

The value obtained by subtracting the jetting temperature of the ink for an insulating layer from the jetting temperature of the ink for an electromagnetic wave shielding layer is preferably 15° C. to 30° C. and more preferably 15° C. to 25° C.

The jetting temperature of the ink for an insulating layer is preferably 40° C. to 60° C. and more preferably 45° C. to 55° C.

### <Second Step>

The manufacturing method according to the present disclosure includes a second step.

The second step is a step of applying an ink for an electromagnetic wave shielding layer onto the insulating layer and onto the ground electrode to form an electromagnetic wave shielding layer.

It is preferable that the formed electromagnetic wave shielding layer is a layer having conductivity.

In the present disclosure, the term “conductive” means properties of having a volume resistivity of less than 10⁸Ω·cm.

The ink for an electromagnetic wave shielding layer is an ink containing a metal compound that is at least one selected from the group consisting of a metal salt and a metal complex.

Accordingly, the resistance of the formed electromagnetic wave shielding layer is reduced as compared with a case of using an ink containing metal particles and not containing the metal compound. The reason for this is considered to be that, by using the above-described ink containing a metal compound, it is possible to form an electromagnetic wave shielding layer having a denser structure (that is, no gap between metal particles) as compared with the case of using an ink containing metal particles and not containing the metal compound.

As a result, in a case of using the above-described ink for an electromagnetic wave shielding layer, containing a metal compound, the electromagnetic wave-shielding properties of the formed electromagnetic wave shielding layer are improved.

### (Ink for Electromagnetic Wave Shielding Layer)

The ink for an electromagnetic wave shielding layer contains a metal compound that is at least one selected from the group consisting of a metal salt and a metal complex.

The ink for an electromagnetic wave shielding layer may contain a solvent, a resin, an additive, and the like.

Hereinafter, a preferred aspect of the ink for an electromagnetic wave shielding layer, which contains a metal complex as the metal compound, will be described as “metal complex ink”, and a preferred aspect of the ink for an electromagnetic wave shielding layer, which contains a metal salt as the metal compound, will be described as “metal salt ink”.

The ink for an electromagnetic wave shielding layer, which contains both the metal complex and the metal salt as the metal compound, may be an aspect in which the “metal complex ink” and the “metal salt ink” are appropriately combined.

### (Metal Complex Ink)

The metal complex ink is, for example, an ink obtained by dissolving a metal complex in a solvent.

### —Metal Complex—

Examples of metals constituting the metal complex include silver, copper, gold, aluminum, magnesium, tungsten, molybdenum, zinc, nickel, iron, platinum, tin, copper, and lead. Among these, from the viewpoint of conductivity, the metal constituting the metal complex preferably includes at least one selected from the group consisting of silver, gold, platinum, nickel, palladium, and copper, and more preferably includes silver.

The content of the metal contained in the metal complex ink is preferably 1% by mass to 40% by mass, more preferably 5% by mass to 30% by mass, and still more preferably 7% by mass to 20% by mass, with respect to the total amount of the metal complex ink, in terms of the metal element.

The metal complex can be obtained, for example, by reacting a metal salt with a complexing agent. Examples of a manufacturing method of the metal complex include a method of adding a metal salt and a complexing agent to a solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include a metal oxide, thiocyanate, sulfide, chloride, cyanide, cyanate, carbonate, acetate, nitrate, nitrite, sulfate, phosphate, perchlorate, tetrafluoroborate, an acetyl acetonate complex salt, and carboxylate.

From the viewpoint of conductivity and storage stability, the metal salt is preferably a carboxylate. The carboxylic acid forming the carboxylate is preferably at least one selected from the group consisting of carboxylic acids having 1 to 20 carbon atoms, and more preferably a carboxylic acid having 1 to 16 carbon atoms, and still more preferably a fatty acid having 2 to 12 carbon atoms. The fatty acid may be linear or branched or may have a substituent.

Examples of the linear fatty acid include formic acid, acetic acid, propionic acid, butyric acid, valeric acid, caproic acid, caprylic acid, pelargonic acid, capric acid, undecanoic acid, lauric acid, myristic acid, palmitic acid, stearic acid, palmitoleic acid, oleic acid, linoleic acid, and linolenic acid.

Examples of the branched fatty acid include isobutyric acid, isovaleric acid, 2-ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of the carboxylic acid having a substituent include hexafluoroacetylacetonate, glycolic acid, lactic acid, 3-hydroxybutyric acid, 2-methyl-3-hydroxybutyric acid, 3-methoxybutyric acid, and acetoacetic acid.

Examples of the polyfunctional carboxylic acid include oxalic acid, succinic acid, glutaric acid, malonic acid, acetonedicarboxylic acid, 3-hydroxyglutaric acid, 2-methyl-3-hydroxyglutaric acid, and 2,2,4,4-hydroxyglutaric acid, and citric acid.

Among these, the metal salt is preferably an alkyl carboxylate having 2 to 12 carbon atoms, oxalate, or acetoacetate, and more preferably an alkyl carboxylic acid having 2 to 12 carbon atoms.

Examples of the complexing agent include an amine, an ammonium carbamate-based compound, an ammonium carbonate-based compound, and an ammonium bicarbonate compound. Among these, from the viewpoint of the conductivity and stability of the metal complex, the complexing agent preferably includes at least one selected from the group consisting of an amine, an ammonium carbamate-based compound, and an ammonium carbonate-based compound.

The metal complex has a structure derived from a complexing agent, and preferably has a structure derived from at least one selected from the group consisting of an amine, an ammonium carbamate-based compound, and an ammonium carbonate-based compound.

Examples of the amine as a complexing agent include ammonia, a primary amine, a secondary amine, a tertiary amine, and a polyamine.

Examples of the primary amine having a linear alkyl group include methylamine, ethylamine, n-propylamine, n-butylamine, n-pentylamine, n-hexylamine, n-heptylamine, n-octylamine, n-nonylamine, n-decylamine, undecylamine, n-dodecylamine, n-tridecylamine, n-tetradecylamine, n-pentadecylamine, n-hexadecylamine, n-heptadecylamine, and n-octadecylamine.

Examples of the primary amine having a branched alkyl group include isopropylamine, sec-butylamine, tert-butylamine, isopentylamine, 2-ethylhexylamine, and tert-octylamine.

Examples of the primary amine having an alicyclic structure include cyclopentylamine, cyclohexylamine, and dicyclohexylamine.

Examples of the primary amine having a hydroxyalkyl group include ethanolamine, diethanolamine, triethanolamine, N-methylethanolamine, propanolamine, isopropanolamine, dipropanolamine, diisopropanolamine, tripropanolamine, and triisopropanolamine.

Examples of the primary amine having an aromatic ring include benzylamine, N,N-dimethylbenzylamine, phenylamine, diphenylamine, triphenylamine, aniline, N,N-dimethylaniline, N,N-dimethyl-p-toluidine, 4-aminopyridine, and 4-dimethylaminopyridine.

Examples of the secondary amine include dimethylamine, diethylamine, dipropylamine, dibutylamine, diphenylamine, dicyclopentylamine, methylbutylamine, diethanolamine, N-methylethanolamine, dipropanolamine, and diisopropanolamine.

Examples of the tertiary amine include trimethylamine, triethylamine, tripropylamine, triethanolamine, tripropanolamine, triisopropanolamine, triphenylamine, N,N-dimethylaniline, N,N-dimethyl-p-toluidine, and 4-dimethylaminopyridine.

Examples of the polyamine include ethylenediamine, 1,2-diaminopropane, 1,3-diaminopropane, diethylenetriamine, triethylenetetramine, tetramethylenepentamine, hexamethylenediamine, tetraethylenepentamine, and a combination of these.

The amine is preferably an alkylamine, preferably an alkylamine having 2 to 12 carbon atoms, and more preferably a primary alkylamine having 2 to 8 carbon atoms.

The metal complex may be configured of one amine or two or more amines.

In reacting the metal salt with an amine, a ratio of the molar amount of the amine to a molar amount of the metal salt is preferably 1/1 to 15/1, and more preferably 1.5/1 to 6/1. In a case in which the above ratio is within the above range, the complex formation reaction is completed, and a transparent solution is obtained.

Examples of the ammonium carbamate-based compound as a complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate, isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Examples of the ammonium carbonate-based compound as a complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Examples of the ammonium bicarbonate-based compound as a complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In reacting the metal salt with an ammonium carbamate-based compound, an ammonium carbonate-based compound, or an ammonium bicarbonate-based compound, a ratio of a molar amount of the ammonium carbamate-based compound, the ammonium carbonate-based compound, or the ammonium bicarbonate-based compound to the molar amount of the metal salt is preferably 0.01/1 to 1/1, and more preferably 0.05/1 to 0.6/1.

The content of the metal complex in the metal complex ink is preferably 10% by mass to 90% by mass, and more preferably 10% by mass to 40% by mass, with respect to the total amount of the metal complex ink. In a case in which the content of the metal complex is 10% by mass or more, the surface resistivity is further reduced. In a case in which the content of the metal complex is 90% by mass or less, jettability is improved in a case in which the metal particle ink is applied by using an ink jet recording method.

### —Solvent—

The metal complex ink preferably contains a solvent. The solvent is not particularly limited as long as it can dissolve the component contained in the metal complex ink, such as the metal complex. From the viewpoint of ease of manufacturing, a boiling point of the solvent is preferably 30° C. to 300° C., more preferably 50° C. to 200° C., and still more preferably 50° C. to 150° C.

The content of the solvent in the metal complex ink is preferably set such that the concentration of metal ions with respect to the metal complex (the amount of the metal present as free ions with respect to 1 g of the metal complex) is 0.01 mmol/g to 3.6 mmol/g, and more preferably set such that the concentration of metal ions is 0.05 mmol/g to 2 mmol/g. In a case in which the concentration of metal ions is within the above range, the metal complex ink has excellent fluidity and can obtain conductivity.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water. The metal complex ink may contain only one solvent or two or more solvents.

The hydrocarbon is preferably a linear or branched hydrocarbon having 6 to 20 carbon atoms. Examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms. The cyclic hydrocarbons can include, for example, cyclohexane, cycloheptane, cyclooctane, cyclononane, cyclodecane, and decalin.

Examples of the aromatic hydrocarbon include benzene, toluene, xylene, and tetraline.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, eicosyl alcohol, and isoeicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

### —Reducing Agent—

The metal complex ink may contain a reducing agent. In a case in which the metal complex ink contains a reducing agent, reduction of the metal complex into a metal is facilitated.

Examples of the reducing agent include a borohydride metal salt, an aluminum hydride salt, an amine, an alcohol, an aldehyde, an organic acid, reduced sugar, a sugar alcohol, sodium sulfite, a hydrazine compound, dextrin, hydroquinone, hydroxylamine, ethylene glycol, glutathione, and an oxime compound.

The reducing agent may be the oxime compound described in JP2014-516463A.

Examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The metal complex ink may contain one reducing agent or two or more reducing agents.

The content of the reducing agent in the metal complex ink is not particularly limited, but is preferably 0.1% by mass to 20% by mass, more preferably 0.3% by mass to 10% by mass, and still more preferably 1% by mass to 5% by mass, with respect to the total amount of the metal complex ink.

### —Resin—

The metal complex ink may contain a resin. In a case in which the metal complex ink contains a resin, adhesiveness of the metal complex ink to the electronic substrate is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The metal complex ink may contain one resin or two or more resins.

### —Additive—

As long as the effects of the present disclosure are not reduced, the metal complex ink may further contain additives such as an inorganic salt, an organic salt, an inorganic oxide such as silica, a surface conditioner, a wetting agent, a crosslinking agent, an antioxidant, a rust inhibitor, a heat-resistant stabilizer, a surfactant, a plasticizer, a curing agent, a thickener, and a silane coupling agent. The total content of the additives in the metal complex ink is preferably 20% by mass or less with respect to the total amount of the metal complex ink.

The viscosity of the metal complex ink is not particularly limited. The viscosity of the metal complex ink need only be 0.001 Pa·s to 5,000 Pas, and is preferably 0.001 Pa·s to 100 Pas. In a case in which the metal complex ink is applied by a spray method or an ink jet recording method, the viscosity of the metal complex ink is preferably 1 mPa·s to 100 mPa·s, more preferably 2 mPa·s to 50 mPa·s, and still more preferably 3 mPa·s to 30 mPa·s.

The viscosity of the metal complex ink is a value measured at 25° C. using a viscometer. The viscosity is measured using, for example, a VISCOMETER TV-22 type viscometer (manufactured by Toki Sangyo Co., Ltd.).

The surface tension of the metal complex ink is not particularly limited, and is preferably 20 mN/m to 45 mN/m and more preferably 25 mN/m to 35 mN/m. The surface tension is a value measured at 25° C. using a surface tension meter.

The surface tension of the metal complex ink is measured using, for example, DY-700 (manufactured by Kyowa Interface Science Co., Ltd.).

### (Metal Salt Ink)

The metal salt ink is, for example, an ink composition obtained by dissolving a metal salt in a solvent.

### —Metal Salt—

Examples of metals constituting the metal salt include silver, copper, gold, aluminum, magnesium, tungsten, molybdenum, zinc, nickel, iron, platinum, tin, copper, and lead. Among these, from the viewpoint of conductivity, the metal constituting the metal salt preferably includes at least one selected from the group consisting of silver, gold, platinum, nickel, palladium, and copper, and more preferably includes silver.

The content of the metal contained in the metal salt ink is preferably 1% by mass to 40% by mass, more preferably 5% by mass to 30% by mass, and still more preferably 7% by mass to 20% by mass, with respect to the total amount of the metal salt ink, in terms of the metal element.

The content of the metal salt in the metal salt ink is preferably 10% by mass to 90% by mass, and more preferably 10% by mass to 60% by mass, with respect to the total amount of the metal salt ink. In a case in which the content of the metal salt is 10% by mass or more, the surface resistivity is further reduced. In a case in which the content of the metal salt is 90% by mass or less, jettability is improved in a case in which the metal particle ink is applied by using a spray method or an ink jet recording method.

As the metal salt, the same metal salt as the metal salt used in the metal complex ink can be used. Among these, the metal salt is preferably a carboxylate. As the carboxylic acid forming the carboxylate, an alkyl carboxylate having 6 to 12 carbon atoms or acetoacetic is preferable, and an alkyl carboxylate having 6 to 12 carbon atoms is more preferable. Two or more carboxylates may be combined.

The metal salt may be a commercially available product or may be manufactured by a known method. A silver salt is manufactured, for example, by the following method.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time using an ultrasonic stirrer, and the formed precipitate is washed with ethanol and decanted. All of these steps can be performed at room temperature (25° C.). A mixing ratio of the silver compound and the formic acid or fatty acid having 1 to 30 carbon atoms is preferably 1:2 to 2:1, and more preferably 1:1, in terms of molar ratio.

The metal salt ink may contain a solvent, a reducing agent, a resin, and additives. Preferred aspects of the solvent, the reducing agent, the resin, and the additives are the same as the preferred aspects of the solvent, the reducing agent, the resin, and the additives which may be contained in the metal complex ink.

### —Solvent—

The metal salt ink preferably contains a solvent.

A type of the solvent is not particularly limited as long as it can dissolve the metal salt contained in the metal salt ink.

From the viewpoint of ease of manufacturing, the boiling point of the solvent is preferably 30° C. to 300° C., more preferably 50° C. to 300° C., and still more preferably 50° C. to 250° C.

The content of the solvent in the metal salt ink is preferably set such that the concentration of metal ions with respect to the metal salt (the amount of the metal present as free ions with respect to 1 g of the metal salt) is 0.01 mmol/g to 3.6 mmol/g, and more preferably set such that the concentration of metal ions is 0.05 mmol/g to 2.6 mmol/g. In a case in which the concentration of metal ions is within the above range, the metal salt ink has excellent fluidity and can obtain the electromagnetic wave-shielding properties.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water.

The metal salt ink may contain only one solvent or two or more solvents.

The solvent preferably contains an aromatic hydrocarbon.

Examples of the aromatic hydrocarbon include benzene, toluene, xylene, ethylbenzene, propylbenzene, isopropylbenzene, butylbenzene, isobutylbenzene, t-butylbenzene, trimethylbenzene, pentylbenzene, hexylbenzene, tetraline, benzyl alcohol, phenol, cresol, methyl benzoate, ethyl benzoate, propyl benzoate, and butyl benzoate.

From the viewpoint of compatibility with other components, the number of aromatic rings in the aromatic hydrocarbon is preferably 1 or 2, and more preferably 1.

From the viewpoint of ease of manufacturing, a boiling point of the aromatic hydrocarbon is preferably 50° C. to 300° C., more preferably 60° C. to 250° C., and still more preferably 80° C. to 200° C.

The solvent may contain an aromatic hydrocarbon and a hydrocarbon other than the aromatic hydrocarbon.

Examples of the hydrocarbon other than the aromatic hydrocarbon include a linear hydrocarbon having 6 to 20 carbon atoms, a branched hydrocarbon having 6 to 20 carbon atoms, and an alicyclic hydrocarbon having 6 to 20 carbon atoms.

Examples of the hydrocarbon other than the aromatic hydrocarbon include pentane, hexane, heptane, octane, nonane, decane, undecane, dodecane, tridecane, tetradecane, pentadecane, hexadecane, octadecane, nonadecane, decalin, cyclohexane, cycloheptane, cyclooctane, cyclononane, cyclodecane, decene, a terpene-based compound, and icosane.

The hydrocarbon other than the aromatic hydrocarbon preferably contains an unsaturated bond.

Examples of the hydrocarbon containing an unsaturated bond other than the aromatic hydrocarbon include a terpene-based compound.

Depending on the number of isoprene units constituting the terpene-based compound, the terpene-based compound is classified into, for example, a hemiterpene, a monoterpene, a sesquiterpene, a diterpene, a sesterterpene, a triterpene, a sesquarterpene, and a tetraterpene.

The terpene-based compound as the solvent may be any of the above compounds, but is preferably a monoterpene.

Examples of the monoterpene include pinene (α-pinene and β-pinene), terpineol (α-terpineol, β-terpineol, and γ-terpineol), myrcene, camphene, limonene (d-limonene, 1-limonene, and dipentene), ocimene (α-ocimene and β-ocimene), alloocimene, phellandrene (α-phellandrene and β-phellandrene), terpinene (α-terpinene and γ-terpinene), terpinolene (α-terpinolene, β-terpinolene, γ-terpinolene, and δ-terpinolene), 1,8-cineole, 1,4-cineole, sabinene, paramenthadiene, and carene (δ-3-carene).

As the monoterpene, a cyclic monoterpene is preferable, and pinene, terpineol, or carene is more preferable.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, eicosyl alcohol, and isoeicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

The viscosity of the metal salt ink is not particularly limited. The viscosity of the metal salt ink need only be 0.001 Pa·s to 5,000 Pa·s, and is preferably 0.001 Pa·s to 100 Pa·s. In a case in which the metal salt ink is applied by a spray method or an ink jet recording method, the viscosity of the metal salt ink is preferably 1 mPa·s to 100 mPa·s, more preferably 2 mPa·s to 50 mPa·s, and still more preferably 3 mPa·s to 30 mPa·s.

The viscosity of the metal salt ink is a value measured at 25° C. by using a viscometer. The viscosity is measured using, for example, a VISCOMETER TV-22 type viscometer (manufactured by Toki Sangyo Co., Ltd.).

The surface tension of the metal salt ink is not particularly limited, and is preferably 20 mN/m to 45 mN/m and more preferably 25 mN/m to 35 mN/m. The surface tension is a value measured at 25° C. using a surface tension meter.

The surface tension of the metal salt ink is measured using, for example, DY-700 (manufactured by Kyowa Interface Science Co., Ltd.).

### (Application of Ink for Electromagnetic Wave Shielding Layer)

In the second step, the ink for an electromagnetic wave shielding layer is jetted from the ink jet head B (that is, an ink jet head for jetting the ink for an electromagnetic wave shielding layer) to be applied onto the insulating layer and onto the ground electrode.

As a method of jetting the ink for an electromagnetic wave shielding layer from the ink jet head B to apply the ink for an electromagnetic wave shielding layer, a known method can be adopted, and the method is not particularly limited.

As a preferred aspect of the method of jetting the ink for an electromagnetic wave shielding layer from the ink jet head B to apply the ink for an electromagnetic wave shielding layer, for example, the above-described preferred aspect of the method of jetting the ink for an insulating layer from the ink jet head A to apply the ink for an insulating layer in the first step may be appropriately referred to.

A resolution in the application of the ink for an electromagnetic wave shielding layer onto the insulating layer and onto the ground electrode (that is, in a case of jetting the ink for an electromagnetic wave shielding layer from the ink jet head B) is preferably 600 dpi or more and more preferably 1,200 dpi or more.

Accordingly, it is possible to obtain a denser electromagnetic wave shielding layer, so that the conductivity of the electromagnetic wave shielding layer can be further improved, and as a result, the electromagnetic wave-shielding properties of the electromagnetic wave shielding layer can be further improved.

The upper limit of the above-described resolution is, for example, 3,000 dpi.

From the viewpoint of further improving the electromagnetic wave-shielding properties of the electromagnetic wave shielding layer, a jetting frequency in the application of the ink for an electromagnetic wave shielding layer onto the insulating layer and onto the ground electrode (that is, in a case of jetting the ink for an electromagnetic wave shielding layer from the ink jet head B) is preferably 1 kHz to 30 kHz, more preferably 1 kHz to 20 kHz, and still more preferably 1 kHz to 10 KHz.

### (Jetting Temperature of Ink for Electromagnetic Wave Shielding Layer)

It is sufficient that the jetting temperature in the jetting of the ink for an electromagnetic wave shielding layer from the ink jet head B satisfies the above-described relationship with the jetting temperature in the jetting of the ink for an insulating layer from the ink jet head A.

The jetting temperature of the ink for an electromagnetic wave shielding layer is, for example, 10° C. to 50° C., preferably 20° C. to 40° C. and more preferably 25° C. to 35° C.

In the second step, it is preferable that a temperature of the electronic substrate in the jetting of the ink for an electromagnetic wave shielding layer from the ink jet head B is higher than the jetting temperature in the jetting of the ink for an electromagnetic wave shielding layer from the ink jet head B by 25° C. or higher.

As a result, the conductivity of the formed electromagnetic wave shielding layer, that is, the electromagnetic wave-shielding properties can be further improved.

In this aspect, as will be described later, the electronic substrate before applying the ink for an electromagnetic wave shielding layer may be heated to a temperature of 50° C. or higher and lower than 110° C. in advance by a heating unit such as a platen, and the ink for an electromagnetic wave shielding layer may be jetted from the ink jet head B to the electronic substrate heated to this temperature.

(Heating and/or Irradiation with Active Energy Ray)

In the second step, the electromagnetic wave shielding layer is formed by performing at least one of heating or irradiation with active energy ray on the ink for an electromagnetic wave shielding layer, applied onto the insulating layer and onto the ground electrode.

As for a preferred aspect in a case in which the ink for an electromagnetic wave shielding layer is irradiated with active energy ray, the preferred aspect of the irradiation of the ink for an insulating layer with active energy ray in the first step can be appropriately referred to.

A heating method in a case of heating the ink for an electromagnetic wave shielding layer is not particularly limited, and the heating can be performed by a known method such as heating using a heating unit, for example, a platen or a furnace, and irradiation with infrared rays.

It is also preferable that the second step includes heating the electronic substrate before applying the ink for an electromagnetic wave shielding layer to a temperature of 50° C. or higher and lower than 110° C., and applying the ink for an electromagnetic wave shielding layer onto the insulating layer and onto the ground electrode in the electronic substrate heated to the temperature of 50° C. or higher and lower than 110° C.

As a result, the conductivity of the formed electromagnetic wave shielding layer, that is, the electromagnetic wave-shielding properties can be further improved.

The heating in this aspect is preferably performed by a platen.

### EXAMPLES

Hereinafter, examples of the present disclosure will be shown, but the present disclosure is not limited to the following examples.

### Example 1

### <Preparation of Ink for Insulating Layer>

4.0 g of 2-(dimethylamino)-2-(4-methylbenzyl)-1-(4-morpholinophenyl)-butan-1-one (trade name “Omnirad 379”, manufactured by IGM Resins B.V.) as a polymerization initiator, 2.0 g of 2-isopropylthioxanthone (trade name “SPEEDCURE ITX”, manufactured by Lambson Ltd.; hereinafter, also referred to as “ITX”) as a sensitizer, 30.0 g of isobornyl acrylate (manufactured by FUJIFILM Wako Pure Chemical Corporation; hereinafter, also referred to as “IBOA”) as a monofunctional acrylate X2 (that is, a monofunctional acrylate having a molecular weight of 200 or more and including a ring structure), 15.0 g of cyclic trimethylolpropane formal monacrylate (manufactured by OSAKA ORGANIC CHEMICAL INDUSTRY LTD., VISCOAT #200; hereinafter, also referred to as “CTFA”) as the monofunctional acrylate X2, 20.0 g of N-vinylcaprolactam (hereinafter, also referred to as “NVC”) as a monofunctional monomer, 10.0 g of 1,6-hexanediol diacrylate (hereinafter, also referred to as “1,6-HDDA”) as a bifunctional monomer, 10.0 g of hexanediol diacrylate (manufactured by Sartomer Company Inc., CD561) as a bifunctional monomer, and 9.0 g of trimethylolpropane triacrylate (manufactured by FUJIFILM Wako Pure Chemical Corporation; hereinafter, also referred to as “TMPTA”) as a trifunctional monomer were added to a 300 mL beaker made of resin; and the mixture was stirred for 20 minutes under the conditions of 5,000 rpm at 25° C. using a mixer (trade name “L4R”, manufactured by Silverson), thereby obtaining an ink for an insulating layer. The viscosity of the ink for an insulating layer at 25° C. was measured using a TV-22 type viscometer manufactured by Toki Sangyo Co., Ltd., and the value was as shown in Table 1.

### <Preparation of Ink for Electromagnetic Wave Shielding Layer>

Isobutylammonium carbonate (6.08 g) and 15.0 g of isopropyl alcohol were added to a three-neck flask of 50 mL, and dissolved.

Next, 2.0 g of silver oxide was added thereto and reacted at a normal temperature for 2 hours, thereby obtaining a homogeneous solution.

Furthermore, 0.3 g of 2-hydroxy-2-methylpropylamine was added thereto and stirred, thereby obtaining a solution containing a silver complex.

The obtained solution was filtered using a membrane filter made of polytetrafluoroethylene (PTFE) having a pore diameter of 0.45 μm, thereby obtaining an ink for an electromagnetic wave shielding layer.

The metal component in the ink for an electromagnetic wave shielding layer was a metal compound (specifically, a silver complex).

### <Preparation of Electronic Substrate (Preparation Step)>

The shielding can and the frame of the LTE module manufactured by Quectel, Inc. were removed. After removing a solder of a metal wire on the substrate where the shielding can and the frame were bonded, the flux was removed using a flux washing agent for a print substrate (trade name “goot BS-W20B”), thereby obtaining an electronic substrate A.

Same as in the electronic substrate 10 shown in FIG. 1, the electronic substrate A had a plurality of electronic components and discontinuous frame shape ground electrode that surrounded the plurality of electronic components.

In the electronic substrate A, the width of the ground electrode was 0.5 mm, and the region surrounded by the ground electrode was 25.5 mm×21.5 mm.

In addition, the height of the ground electrode was 100 μm based on a surface of the wiring board on a side where the electronic components were disposed.

### <Formation of Insulating Layer (First Step)>

An ink cartridge (for 10 picoliters) of an ink jet recording device (trade name “DMP-2850” manufactured by Fujifilm Dimatix Inc.) was filled with the ink for an insulating layer.

As image recording conditions, the resolution was set to 2510 dots per inch (dpi), the amount of droplets was set to 10 picoliters per dot, the jetting frequency was set to 16 kHz, the jetting temperature was set to 45° C., and the ink jet head (hereinafter, also referred to as an IJ head) scanning speed was set to 16 m/s.

Image data of the same region (25.5 mm×21.5 mm) as the ground region surrounded by the ground electrode in the electronic substrate was prepared. A cycle of applying the ink for an insulating layer using the image data and irradiating the ink for an insulating layer with ultraviolet rays was repeated ten times (that is, the number of laminations was set to 10).

The irradiation with ultraviolet rays was performed by using an ultraviolet irradiation device (trade name “UV SPOT CURE OmniCure S2000” manufactured by Lumen Dynamics Group Inc.) installed next to the ink jet head (specifically, a portion 7 cm away from the nozzle of the ink jet head).

The illuminance of the ultraviolet rays was set to 8 W/cm² and the irradiation was performed for 0.1 seconds per irradiation, so that the exposure amount per exposure was 0.8 J/cm².

The time from the application of the ink for an insulating layer to the start of the irradiation with active energy ray was adjusted to 0.44 seconds.

In this manner, the insulating layer was formed on the electronic component in the electronic substrate (specifically, on the entire ground region surrounded by the ground electrode).

### <Formation of Electromagnetic Wave Shielding Layer (Second Step)>

An ink cartridge (for 10 picoliters) of an ink jet recording device (trade name “DMP-2850”, manufactured by Fujifilm Dimatix Inc.) was filled with the ink for an electromagnetic wave shielding layer.

As image recording conditions, the resolution was set to 2510 dots per inch (dpi), the amount of droplets was set to 10 picoliters per dot, the jetting frequency was set to 4 kHz, the jetting temperature was set to 30° C., and the IJ head scanning speed was set to 4 m/s.

The electronic substrate on which the insulating layer had been formed was heated in advance to 60° C. by a platen.

Image data of a region (26.5 mm×22.5 mm) covering the insulating layer and the ground electrode in the electronic substrate was prepared.

Using the image data, a cycle of applying the ink for an electromagnetic wave shielding layer onto the insulating layer and onto the ground electrode in the electronic substrate heated to 60° C., and heating the ink for an electromagnetic wave shielding layer at 180° C. for 60 minutes using an oven was repeated five times (that is, the number of laminations was set to 5).

In this manner, an electromagnetic wave shielding layer was formed on the electronic substrate so as to coat the insulating layer and be electrically connected to the ground electrode, thereby obtaining an electronic device.

### <Evaluation>

In the above-described manufacturing of the electronic device, the following evaluations were performed.

The results are shown in Table 1.

### (Pattern Quality of Insulating Layer)

At the stage in which the formation of the insulating layer was completed, the pattern of the insulating layer was confirmed, and the pattern quality of the insulating layer was evaluated according to the following evaluation standard.

In the following evaluation standard, the rank of the most excellent pattern quality of the insulating layer is 5.

### —Evaluation Standard for Pattern Quality of Insulating Layer—

5: no streak-like deterioration was confirmed in the pattern of the insulating layer, and no overflow onto the ground electrode was confirmed.
4: streak-like deterioration was not confirmed in the pattern of the insulating layer, but the overflow onto the ground electrode was confirmed, and the maximum overflow width was 50 μm or less.
3: streak-like deterioration was confirmed in the pattern of the insulating layer, and the overflow onto the ground electrode was confirmed and the maximum overflow width was 50 μm or less.
2: pattern of the insulating layer was confirmed to have a portion protruding to the ground electrode, and the maximum overflow width was more than 50 μm and 100 μm or less.
1: pattern of the insulating layer was confirmed to have a portion protruding to the ground electrode, and the maximum overflow width was more than 100 μm.

### <Electromagnetic Wave-Shielding Properties>

The obtained electronic device was subjected to a cycle test of 200 cycles at a temperature of −30° C. to 90° C.

The communication of the electronic device after 200 cycles of the cycle test was made with LTE BAND 13, and near magnetic field measurement was executed at a frequency of 777 MHz using a near magnetic field measuring device (trade name “SmartScan 550”, manufactured by API Corporation). A noise suppression level (unit: dB) in the near magnetic field measurement was measured, and the electromagnetic wave-shielding properties were evaluated based on the obtained noise suppression level according to the following evaluation standard.

In the following evaluation standard, the rank of the most excellent electromagnetic wave-shielding properties is 5.

### —Evaluation Standard for Electromagnetic Wave-Shielding Properties—

5: noise suppression level was −40 dB or more.
4: noise suppression level was more than −40 dB and −30 dB or less.
3: noise suppression level was more than −30 dB and −20 dB or less.
2: noise suppression level was more than −20 dB.
1: breakage and peeling were significant after the cycle test, and the evaluation of electromagnetic wave-shielding properties could not be performed.

### <Durability>

The obtained electronic device was subjected to a cycle test of 200 cycles at a temperature of −30° C. to 90° C.

Before and after 200 cycles of the cycle test, the appearance of the insulating layer and the electromagnetic wave shielding layer in the electronic device was observed by visual observation and a microscope, and the change in appearance before and after the cycle test was confirmed.

Based on the confirmed results, the durability of the electronic device was evaluated according to the following evaluation standard.

In the following evaluation standard, the rank of the most excellent durability is 5.

### —Evaluation Standard for Durability—

5: no change in appearance was observed in a case of being visually observed or observed under a microscope.
4: no change in appearance was visually confirmed, but the change in appearance was confirmed by microscopic observation.
3: there were no breakage and peeling, but an external change in appearance was visually confirmed.
2: there were slight breakage and peeling.
1: breakage and peeling were significant.

### Examples 2 to 18

The same operation as in Example 1 was performed, except that the combination of the formation of the ink for an insulating layer, the insulating layer formation conditions, and the electromagnetic wave shielding layer formation conditions was changed as shown in Tables 1 and 2.

The results are shown in Tables 1 and 2.

The abbreviations in Tables 1 and 2 are as follows.
IBOA . . . isobornyl acrylate
CTFA . . . cyclic trimethylolpropane formal monacrylate
CHA . . . cyclohexyl acrylate
PEA . . . phenoxyethyl acrylate
IDA . . . isodecyl acrylate
NVC . . . N-vinylcaprolactam
1,6-HDDA . . . 1,6-hexanediol diacrylate
CD561 . . . alkoxylated hexanediol diacrylate
TMPTA . . . trimethylolpropane triacrylate
Omnirad 379 . . . polymerization initiator which is an α-aminoalkylphenone compound (manufactured by IGM Resins B.V.)
ITX . . . 2-isopropylthioxanthone

### Comparative Examples 1 to 5

The same operation as in Example 1 was performed, except that the combination of the metal component in the ink for an electromagnetic wave shielding layer, the formation of the ink for an insulating layer, the insulating layer formation conditions, and the electromagnetic wave shielding layer formation conditions was changed as shown in Table 1.

The results are shown in Table 3.

Each of the inks for an electromagnetic wave shielding layer of Comparative Examples 1, 3, 4, and 5, in which the metal component was the metal compound, was the same as the ink for an electromagnetic wave shielding layer of Example 1.

The ink for an electromagnetic wave shielding layer of Comparative Example 2, in which the metal component was metal particles, was a silver particle ink prepared as follows.

### <Preparation of Ink for Electromagnetic Wave Shielding Layer of Comparative Example 2 (Silver Particle Ink)>

### —Preparation of Silver Particle Dispersion 1—

As a dispersing agent, 6.8 g of polyvinylpyrrolidone (weight-average molecular weight: 3,000, manufactured by Sigma-Aldrich Corporation) was dissolved in 100 mL of water, thereby preparing a solution a.

In addition, 50.00 g of silver nitrate was dissolved in 200 mL of water, thereby preparing a solution b.

The solution a and the solution b were mixed together and stirred, thereby obtaining a mixed solution. At a room temperature, 78.71 g of an 85% by mass N,N-diethylhydroxylamine aqueous solution was added dropwise to the mixed solution. In addition, a solution obtained by dissolving 6.8 g of polyvinylpyrrolidone in 1,000 mL of water was slowly added dropwise to the mixed solution at a room temperature.

The obtained suspension was passed through an ultrafiltration unit (VIVAFLOW 50 manufactured by Sartorius Stedim Biotech GmbH., molecular weight cut-off: 100,000, number of units: 4) and purified by being passed through purified water until about 5 L of exudate is discharged from an ultrafiltration unit. The supply of purified water was stopped, followed by concentration, thereby obtaining 30 g of a silver particle dispersion 1.

The solid content in this dispersion was 50% by mass, and the solid content in the silver particle dispersion 1, measured by TG-DTA (simultaneous measurement of thermogravimetry and differential thermal analysis) (manufactured by Hitachi High-Tech Corporation, model: STA7000 series), was 96.0% by mass.

The obtained silver particle dispersion 1 was diluted 20-fold with deionized water, and measured using a particle size analyzer FPAR-1000 (manufactured by Otsuka Electronics Co., Ltd) to obtain a volume average particle size of the silver particles. The volume average particle size of the silver particles in the silver particle dispersion 1 was 60 nm.

### —Preparation of Silver Particle Ink A1—

2 g of 2-propanol and 0.1 g of OLFINE E-1010 (manufactured by Nissin Chemical Industry Co., Ltd.) as a surfactant were added to 10 g of the silver particle dispersion, and water was added thereto such that the silver concentration reaches 40% by mass, thereby obtaining a silver particle ink as the ink for an electromagnetic wave shielding layer of Comparative Example 2.

TABLE 1

| | | | Exam- | Exam- | Exam- | Exam- | Exam- | Exam- | Exam- | Exam- | Exam- |
|---|---|---|---|---|---|---|---|---|---|---|---|
| | | | ple 1 | ple 2 | ple 3 | ple 4 | ple 5 | ple 6 | ple 7 | ple 8 | ple 9 |
| Ink for | Monofunctional | IBOA | 30 | 30 | 30 | 30 | 30 | 30 | 30 | 30 | 30 |
| insulating layer | acrylate X2 | CTFA | 15 | 15 | 15 | 15 | 15 | 15 | 15 | 15 | 15 |
| (amount: part | Monofunctional | CHA | | | | | | | | | |
| by mass) | acrylate X | PEA | | | | | | | | | |
| | (molecular | | | | | | | | | | |
| | weight: less | | | | | | | | | | |
| | than 200) | | | | | | | | | | |
| | Monofunctional | IDA | | | | | | | | | |
| | acrylate X | | | | | | | | | | |
| | (not including | | | | | | | | | | |
| | ring structure) | | | | | | | | | | |
| | Monofunctional | NVC | 20 | 20 | 20 | 20 | 20 | 20 | 20 | 20 | 20 |
| | monomer | | | | | | | | | | |
| | (molecular | | | | | | | | | | |
| | weight: less | | | | | | | | | | |
| | than 200) | | | | | | | | | | |
| | Bifunctional | 1,6- | 10 | 10 | 10 | 10 | 10 | 10 | 10 | 10 | 10 |
| | acrylate | HDDA | | | | | | | | | |
| | | CD561 | 10 | 10 | 10 | 10 | 10 | 10 | 10 | 10 | 10 |
| | Trifunctional | TMPTA | 9 | 9 | 9 | 9 | 9 | 9 | 9 | 9 | 9 |
| | acrylate | | | | | | | | | | |
| | Polymerization | Omnirad | 4 | 4 | 4 | 4 | 4 | 4 | 4 | 4 | 4 |
| | initiator | 379 | | | | | | | | | |
| | Sensitizer | ITX | 2 | 2 | 2 | 2 | 2 | 2 | 2 | 2 | 2 |

| | Ink viscosity (mPa · s) | 20 | 20 | 20 | 20 | 20 | 20 | 20 | 20 | 20 |
|---|---|---|---|---|---|---|---|---|---|---|
| Metal component in ink for | | Metal | Metal | Metal | Metal | Metal | Metal | Metal | Metal | Metal |
| electromagnetic wave shielding layer | | com- | com- | com- | com- | com- | com- | com- | com- | com- |
| | | pound | pound | pound | pound | pound | pound | pound | pound | pound |
| Insulating layer | Resolution (dpi) | 2510 | 2510 | 1254 | 600 | 2510 | 2510 | 2510 | 2510 | 2510 |
| formation | Jetting frequency (kHz) | 16 | 24 | 16 | 4 | 16 | 16 | 16 | 16 | 16 |
| condition | Jetting temperature (° C.) | 45 | 45 | 45 | 45 | 40 | 45 | 45 | 45 | 45 |
| (first step) | IJ head scanning speed | 16 | 24 | 32 | 16 | 16 | 16 | 16 | 16 | 16 |
| | (m/s) | | | | | | | | | |
| | Time from completion of | 0.44 | 0.29 | 0.22 | 0.44 | 0.44 | 0.44 | 0.44 | 0.44 | 0.44 |
| | application to start of | | | | | | | | | |
| | exposure (s) | | | | | | | | | |
| | Number of laminations | 10 | 10 | 10 | 10 | 10 | 10 | 10 | 10 | 10 |
| Electromagnetic | Resolution (dpi) | 2510 | 2510 | 2510 | 2510 | 2510 | 2510 | 1254 | 1254 | 600 |
| wave shielding | Jetting frequency (kHz) | 4 | 4 | 4 | 4 | 4 | 4 | 4 | 4 | 4 |
| layer formation | Jetting temperature (° C.) | 30 | 30 | 30 | 30 | 30 | 30 | 30 | 30 | 30 |
| condition | IJ head scanning speed | 4 | 4 | 4 | 4 | 4 | 4 | 8 | 8 | 4 |
| (second step) | (m/s) | | | | | | | | | |
| | Platen temperature (° C.) | 60 | 60 | 60 | 60 | 60 | 50 | 50 | 50 | 50 |
| | Number of laminations | 5 | 5 | 5 | 3 | 5 | 5 | 3 | 3 | 3 |
| | Difference in temperature | 30 | 30 | 30 | 30 | 30 | 20 | 20 | 20 | 20 |
| | (° C.) | | | | | | | | | |
| | [platen temperature − | | | | | | | | | |
| | jetting temperature] | | | | | | | | | |
| Difference in jetting temperature (° C.) | | 15 | 15 | 15 | 15 | 10 | 15 | 15 | 15 | 15 |
| (ink for insulating layer − ink for | | | | | | | | | | |
| electromagnetic wave shielding layer) | | | | | | | | | | |
| Evaluation | Pattern quality of | 4 | 5 | 5 | 5 | 4 | 4 | 4 | 4 | 4 |
| | insulating layer | | | | | | | | | |
| | Electromagnetic wave- | 5 | 5 | 5 | 5 | 5 | 4 | 5 | 4 | 3 |
| | shielding properties | | | | | | | | | |
| | Durability | 5 | 5 | 5 | 5 | 4 | 5 | 4 | 4 | 4 |

TABLE 2

| | | | Exam- | Exam- | Exam- | Exam- | Exam- | Exam- | Exam- | Exam- | Exam- |
|---|---|---|---|---|---|---|---|---|---|---|---|
| | | | ple 10 | ple 11 | ple 12 | ple 13 | ple 14 | ple 15 | ple 16 | ple 17 | ple 18 |
| Ink for | Monofunctional | IBOA | 30 | 30 | 30 | 30 | 20 | | | | 30 |
| insulating layer | acrylate X2 | CTFA | 15 | 15 | | | | 20 | | | 15 |
| (amount: part | Monofunctional | CHA | | | 19 | | | | | | |
| by mass) | acrylate X | PEA | | | | | | | | 20 | |
| | (molecular | | | | | | | | | | |
| | weight: less | | | | | | | | | | |
| | than 200) | | | | | | | | | | |
| | Monofunctional | IDA | | | | | | | 10 | | |
| | acrylate X | | | | | | | | | | |
| | (not including | | | | | | | | | | |
| | ring structure) | | | | | | | | | | |
| | Monofunctional | NVC | 20 | 20 | 20 | 20 | 20 | 20 | 30 | 20 | 20 |
| | monomer | | | | | | | | | | |
| | (molecular | | | | | | | | | | |
| | weight: less | | | | | | | | | | |
| | than 200) | | | | | | | | | | |
| | Bifunctional | 1,6- | 10 | 10 | 20 | | 10 | 10 | 10 | 10 | 10 |
| | acrylate | HDDA | | | | | | | | | |
| | | CD561 | 10 | 10 | 5 | 25 | 35 | 35 | 35 | 35 | 10 |
| | Trifunctional | TMPTA | 9 | 9 | | 19 | 9 | 9 | 9 | 9 | 9 |
| | acrylate | | | | | | | | | | |
| | Polymerization | Omnirad | 4 | 4 | 4 | 4 | 4 | 4 | 4 | 4 | 4 |
| | initiator | 379 | | | | | | | | | |
| | Sensitizer | ITX | 2 | 2 | 2 | 2 | 2 | 2 | 2 | 2 | 2 |

| | Ink viscosity (mPa · s) | 20 | 20 | 14 | 35 | 30 | 30 | 30 | 30 | 20 |
|---|---|---|---|---|---|---|---|---|---|---|
| Metal component in ink for | | Metal | Metal | Metal | Metal | Metal | Metal | Metal | Metal | Metal |
| electromagnetic wave shielding layer | | com- | com- | com- | com- | com- | com- | com- | com- | com- |
| | | pound | pound | pound | pound | pound | pound | pound | pound | pound |
| Insulating layer | Resolution (dpi) | 2510 | 2510 | 2510 | 2510 | 2510 | 2510 | 2510 | 2510 | 2510 |
| formation | Jetting frequency (kHz) | 16 | 16 | 24 | 24 | 24 | 24 | 24 | 24 | 8 |
| condition | Jetting temperature (° C.) | 45 | 45 | 40 | 60 | 45 | 45 | 45 | 45 | 40 |
| (first step) | IJ head scanning speed | 16 | 16 | 24 | 24 | 24 | 24 | 24 | 24 | 8 |
| | (m/s) | | | | | | | | | |
| | Time from completion of | 0.44 | 0.44 | 0.29 | 0.29 | 0.29 | 0.29 | 0.29 | 0.29 | 0.88 |
| | application to start of | | | | | | | | | |
| | exposure (s) | | | | | | | | | |
| | Number of laminations | 10 | 10 | 10 | 10 | 10 | 10 | 10 | 10 | 10 |
| Electromagnetic | Resolution (dpi) | 1254 | 1254 | 2510 | 2510 | 2510 | 2510 | 2510 | 2510 | 2510 |
| wave shielding | Jetting frequency (kHz) | 4 | 4 | 4 | 4 | 4 | 4 | 4 | 4 | 4 |
| layer formation | Jetting temperature (° C.) | 30 | 30 | 30 | 20 | 30 | 30 | 30 | 30 | 30 |
| condition | IJ head scanning speed | 8 | 8 | 4 | 4 | 4 | 4 | 4 | 4 | 4 |
| (second step) | (m/s) | | | | | | | | | |
| | Platen temperature (° C.) | 30 | 80 | 60 | 60 | 60 | 60 | 60 | 60 | 40 |
| | Number of laminations | 3 | 3 | 5 | 5 | 5 | 5 | 5 | 5 | 5 |
| | Difference in | 0 | 50 | 30 | 40 | 30 | 30 | 30 | 30 | 10 |
| | temperature (° C.) | | | | | | | | | |
| | [platen temperature − | | | | | | | | | |
| | jetting temperature] | | | | | | | | | |
| Difference in jetting temperature (° C.) | | 15 | 15 | 10 | 40 | 15 | 15 | 15 | 15 | 10 |
| (ink for insulating layer − ink for | | | | | | | | | | |
| electromagnetic wave shielding layer) | | | | | | | | | | |
| Evaluation | Pattern quality of | 4 | 4 | 3 | 3 | 5 | 5 | 4 | 4 | 3 |
| | insulating layer | | | | | | | | | |
| | Electromagnetic wave- | 3 | 5 | 4 | 4 | 5 | 5 | 4 | 4 | 3 |
| | shielding properties | | | | | | | | | |
| | Durability | 4 | 4 | 5 | 5 | 5 | 5 | 4 | 3 | 3 |

TABLE 3

| | | | Comparative | Comparative | Comparative | Comparative | Comparative |
|---|---|---|---|---|---|---|---|
| | | | Example 1 | Example 2 | Example 3 | Example 4 | Example 5 |
| Ink for | Monofunctional | IBOA | 30 | 30 | 19 | 15 | 30 |
| insulating layer | acrylate X2 | CTFA | 15 | 15 | | 10 | |
| (amount: part | Monofunctional | CHA | | | 35 | | |
| by mass) | acrylate X | | | | | | |
| | (molecular weight: | PEA | | | | | |
| | less than 200) | | | | | | |
| | Monofunctional | IDA | | | | | |
| | acrylate X | | | | | | |
| | (not including ring | | | | | | |
| | structure) | | | | | | |
| | Monofunctional | NVC | 20 | 20 | 20 | 20 | 20 |
| | monomer | | | | | | |
| | (molecular weight: | | | | | | |
| | less than 200) | | | | | | |
| | Bifunctional | 1,6-HDDA | 10 | 10 | 20 | | |
| | acrylate | CD561 | 10 | 10 | 0 | 25 | 25 |
| | Trifunctional | TMPTA | 9 | 9 | 0 | 24 | 19 |
| | acrylate | | | | | | |
| | Polymerization | Omnirad 379 | 4 | 4 | 4 | 4 | 4 |
| | initiator | | | | | | |
| | Sensitizer | ITX | 2 | 2 | 2 | 2 | 2 |

| | Ink viscosity (mPa · s) | 20 | 20 | 10 | 40 | 35 |
|---|---|---|---|---|---|---|
| Metal component in ink for electromagnetic wave | | Metal | Metal | Metal | Metal | Metal |
| shielding layer | | compound | particles | compound | compound | compound |
| Insulating layer | Resolution (dpi) | 2510 | 2510 | 2510 | 2510 | 2510 |
| formation | Jetting frequency (kHz) | 16 | 16 | 24 | 24 | 24 |
| condition | Jetting temperature (° C.) | 35 | 45 | 40 | 60 | 60 |
| (first step) | IJ head scanning speed (m/s) | 16 | 16 | 24 | 24 | 24 |
| | Time from completion of application | 0.44 | 0.44 | 0.29 | 0.29 | 0.44 |
| | to start of exposure (s) | | | | | |
| | Number of laminations | 10 | 10 | 10 | 10 | 10 |
| Electromagnetic | Resolution (dpi) | 2510 | 1254 | 2510 | 2510 | 2510 |
| wave shielding | Jetting frequency (kHz) | 4 | 4 | 4 | 4 | 4 |
| layer formation | Jetting temperature (° C.) | 30 | 30 | 30 | 20 | 15 |
| condition | IJ head scanning speed (m/s) | 4 | 8 | 4 | 4 | 4 |
| (second step) | Platen temperature (° C.) | 40 | 30 | 60 | 25 | 25 |
| | Number of laminations | 5 | 3 | 5 | 5 | 5 |
| | Difference in temperature (° C.) | 10 | 0 | 30 | 5 | 10 |
| | [platen temperature − jetting | | | | | |
| | temperature] | | | | | |
| Difference in jetting temperature (° C.) | | 5 | 15 | 10 | 40 | 45 |
| (ink for insulating layer − ink for electromagnetic | | | | | | |
| wave shielding layer) | | | | | | |
| Evaluation | Pattern quality of insulating layer | 1 | 3 | 2 | 1 | 1 |
| | Electromagnetic wave-shielding | 2 | 1 | 2 | 1 | 1 |
| | properties | | | | | |
| | Durability | 2 | 3 | 2 | 3 | 4 |

As shown in Tables 1 and 2, in the electronic devices of Examples 1 to 18, in which, in the insulating layer forming step (that is, the first step), the ink for an insulating layer, having a viscosity of 12 mPa·s to 35 mPa·s, was applied to form the insulating layer, and in the electromagnetic wave shielding layer forming step (that is, the second step), the ink for an electromagnetic wave shielding layer containing the metal compound was applied to form the electromagnetic wave shielding layer, and the difference in jetting temperature [ink for an insulating layer—ink for an electromagnetic wave shielding layer] was 10° C. to 40° C., the pattern quality of the insulating layer and the electromagnetic wave-shielding properties were excellent.

On the other hand, as shown in Table 3, in Comparative Example 1 in which the difference in jetting temperature [ink for an insulating layer—ink for an electromagnetic wave shielding layer] was lower than 10° C. and in Comparative Example 5 in which the difference in jetting temperature [ink for an insulating layer—ink for an electromagnetic wave shielding layer] was higher than 40° C., the pattern quality of the insulating layer and the electromagnetic wave-shielding properties were deteriorated. It is considered that these decreases were caused by a decrease in jettability of the ink for an insulating layer.

In addition, in Comparative Example 2 in which the ink for an electromagnetic wave shielding layer, containing the metal particles, was used instead of the ink for an electromagnetic wave shielding layer, containing the metal compound, the electromagnetic wave-shielding properties were deteriorated. It is considered that this deterioration was due to a decrease in conductivity of the electromagnetic wave shielding layer.

In addition, in Comparative Example 3 in which the viscosity of the ink for forming an insulating layer was less than 12 mPa·s, the pattern quality of the insulating layer and the electromagnetic wave-shielding properties were deteriorated. It is considered that these decreases were caused by a decrease in jettability of the ink for an insulating layer.

In addition, in Comparative Example 4 in which the viscosity of the ink for forming an insulating layer was more than 35 mPa·s, the pattern quality of the insulating layer and the electromagnetic wave-shielding properties were deteriorated. It is considered that these decreases were caused by a decrease in jettability of the ink for an insulating layer.

From the results of Examples 1 and 18, it was found that, in a case in which the time from the application of the ink for an insulating layer to the start of the exposure in the first step was 0.50 seconds or less (Example 1), the pattern quality of the insulating layer and the electromagnetic wave-shielding properties were further improved. The reason for this is considered to be that the outflow of the ink for an insulating layer was further suppressed.

From the results of Examples 10 and 11, it was found that, in a case in which the platen temperature in the second step (that is, the temperature of the electronic substrate before applying the ink for an electromagnetic wave shielding layer) was 50° C. or higher and lower than 110° C. (Example 11), the electromagnetic wave-shielding properties were further improved.

From the results of Examples 1 and 6, it was found that, in a case in which the difference in temperature in the second step (C) [platen temperature—jetting temperature] (that is, the value obtained by subtracting the jetting temperature of the ink for an electromagnetic wave shielding layer from the temperature of the electronic substrate before applying the ink for an electromagnetic wave shielding layer) was 25° C. or higher (Example 1), the electromagnetic wave-shielding properties were further improved.

From the results of Examples 1 and 9, it was found that, in a case in which the resolution of the ink for an electromagnetic wave shielding layer in the second step was 1,200 dpi or more (Example 1), the electromagnetic wave-shielding properties were further improved.

From the results of Examples 14 to 17, it was found that, in a case in which the ink for an insulating layer includes the monofunctional acrylate X2 satisfying both the requirement that the molecular weight was 200 or more and the requirement that the ring structure was included (Examples 14 and 15), the durability of the insulating layer and the electromagnetic wave shielding layer was further improved.

The disclosure of JP2021-174077 filed on Oct. 25, 2021 is incorporated in the present specification by reference.

All documents, patent applications, and technical standards described in the present specification are herein incorporated by reference to the same extent that each individual document, patent application, or technical standard was specifically and individually indicated to be incorporated by reference.

What is claimed is:

1. A manufacturing method of an electronic device, comprising:
preparing an electronic substrate including a wiring board, an electronic component disposed on the wiring board, and a ground electrode;
forming an insulating layer on the electronic component; and
forming, on the insulating layer and on the ground electrode, an electromagnetic wave shielding layer that covers the insulating layer and is electrically connected to the ground electrode, to obtain an electronic device,
wherein, the forming an insulating layer includes jetting an ink for an insulating layer, which is an active energy ray curable-type ink and has a viscosity at 25° C. of 12 mPa·s to 35 mPa·s, from an ink jet head A to apply the ink for an insulating layer onto the electronic component, and performing an irradiation with active energy ray on the applied ink for an insulating layer,
the forming an electromagnetic wave shielding layer includes jetting an ink for an electromagnetic wave shielding layer, which contains at least one metal compound selected from the group consisting of a metal salt and a metal complex, from an ink jet head B to apply the ink for an electromagnetic wave shielding layer onto the insulating layer and onto the ground electrode, and performing at least one of a heating or an irradiation with active energy ray on the applied ink for an electromagnetic wave shielding layer, and
a jetting temperature in the jetting of the ink for an insulating layer from the ink jet head A is higher than a jetting temperature in the jetting of the ink for an electromagnetic wave shielding layer from the ink jet head B by 10° C. to 40° C.

2. The manufacturing method of an electronic device according to claim 1,
wherein, in the forming an insulating layer, a time from the application of the ink for an insulating layer onto the electronic component to a start of the irradiation with active energy ray is 0.50 seconds or less.

3. The manufacturing method of an electronic device according to claim 1,
wherein, the forming an insulating layer includes jetting the ink for an insulating layer from the ink jet head A while relatively moving the electronic substrate and the ink jet head A at a relative movement speed of 16 cm/sec or more.

4. The manufacturing method of an electronic device according to claim 1,
wherein the forming an electromagnetic wave shielding layer includes
heating the electronic substrate before applying the ink for an electromagnetic wave shielding layer to a temperature of 50° C. or higher and lower than 110° C., and
applying the ink for an electromagnetic wave shielding layer onto the insulating layer and onto the ground electrode in the electronic substrate heated to the temperature of 50° C. or higher and lower than 110° C.

5. The manufacturing method of an electronic device according to claim 1,
wherein, in the forming an electromagnetic wave shielding layer, a temperature of the electronic substrate in the jetting of the ink for an electromagnetic wave shielding layer from the ink jet head B is higher than the jetting temperature in the jetting of the ink for an electromagnetic wave shielding layer from the ink jet head B by 25° C. or higher.

6. The manufacturing method of an electronic device according to claim 1,
wherein, the forming an electromagnetic wave shielding layer includes applying the ink for an electromagnetic wave shielding layer onto the insulating layer and onto the ground electrode in the electronic substrate at a resolution of 1,200 dpi or more.

7. The manufacturing method of an electronic device according to claim 1,
wherein the ink for an insulating layer contains a monofunctional acrylate.

8. The manufacturing method of an electronic device according to claim 7,
wherein the monofunctional acrylate includes a monofunctional acrylate X satisfying at least one of a requirement that a molecular weight is 200 or more or a requirement that a ring structure is included.

9. The manufacturing method of an electronic device according to claim 7,
wherein the monofunctional acrylate includes a monofunctional acrylate X2 satisfying both a requirement that a molecular weight is 200 or more and a requirement that a ring structure is included.
